(19) United States
(12) Patent Application Publication
(10) Pub. No.: US 2025/0133969 A1
(43) Pub. Date: Apr. 24, 2025

(54) RESISTIVE MEMORY CELL TOP ELECTRODE CONTACT WITH REDUCED CORNER EROSION AND METHOD OF FORMING THE SAME

(71) Applicant: Taiwan Semiconductor Manufacturing Company Limited, Hsinchu (TW)

(72) Inventors: Jhih-Bin Chen, Hsinchu (TW); Hsia-Wei Chen, Taipei City (TW); Wen-Ting Chu, Kaohsiung City (TW)

(21) Appl. No.: 18/625,292

(22) Filed: Apr. 3, 2024

Related U.S. Application Data
(60) Provisional application No. 63/592,230, filed on Oct. 23, 2023.

(51) Int. Cl. H10N 70/00; H10B 63/00

(52) U.S. Cl. CPC H10N 70/8418; H10B 63/80; H10N 70/063; H10N 70/8265

(57) ABSTRACT

A device structure includes a first metal interconnect structure formed in a first dielectric material layer; an etch-stop dielectric layer overlying the first dielectric material layer and having an opening having a first width along a first horizontal direction; and a resistive memory cell including a stack of a bottom electrode, a memory material layer, and a top electrode. The bottom electrode includes a plate portion and a via portion located within the opening in the etch-stop dielectric layer. The memory material layer overlies the bottom electrode and is configured to provide at least two states having different electrical resistance. The top electrode overlies the memory material layer. A hard mask plate overlies the top electrode. A periphery of a top surface of the hard mask plate has a second width along the first horizontal direction that is greater than the first width.

### RELATED APPLICATIONS

This application claims the benefit of priority from U.S. Provisional Application No. 63/592,230 entitled “Enlarged RRAM TEVA Landing Window by Vertical Profile through Mitigated Hard Mask Corner Erosion” filed on Oct. 23, 2023, the entire contents of which are hereby incorporated by reference for all purposes.

### BACKGROUND

A resistive memory cell includes a resistive memory element, in which a data bit may be encoded as a low resistance state or as a high resistance state. A plurality of resistive memory cells may be arranged as a two-dimensional array or as a three-dimensional array to provide random access of the resistive memory cells, in which case an array of resistive random access memory (RRAM) cells is provided.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first embodiment structure after formation of complementary metal-oxide-semiconductor (CMOS) transistors, metal interconnect structures formed in dielectric material layers, and a lower connection-via-level dielectric layer according to an embodiment of the present disclosure.

FIG. 2A is a vertical cross-sectional view of the first embodiment structure after deposition and patterning of an etch-stop dielectric layer according to an embodiment of the present disclosure.

FIG. 2B is a magnified vertical cross-sectional view of a region of the first embodiment structure of FIG. 2A.

FIG. 2C illustrate top-down views of various configurations of the first embodiment structure of FIGS. 2A and 2B.

FIGS. 3A-3C are sequential vertical cross-sectional views of a region of the first embodiment structure during formation of a resistive memory cell according to an embodiment of the present disclosure.

FIG. 3D illustrate top-down views of various configurations of the first embodiment structure of FIG. 3C.

FIG. 4A is a vertical cross-sectional view of the first embodiment structure after formation of a dielectric capping layer, a memory-level dielectric layer, and a dielectric pad layer according to an embodiment of the present disclosure.

FIG. 4B is a magnified view of a region of the first embodiment structure of FIG. 4A.

FIG. 5A is a vertical cross-sectional view of the first embodiment structure after patterning the dielectric pad layer according to an embodiment of the present disclosure.

FIG. 5B is a magnified vertical cross-sectional view of a region of the first embodiment structure of FIG. 5A.

FIG. 6A is a vertical cross-sectional view of the first embodiment structure after formation of via cavities according to an embodiment of the present disclosure.

FIG. 6B is a magnified vertical cross-sectional view of a region of the first embodiment structure of FIG. 6A.

FIG. 7A is a vertical cross-sectional view of the first embodiment structure after formation of contact via structures according to an embodiment of the present disclosure.

FIG. 7B is a magnified vertical cross-sectional view of a region of the first embodiment structure of FIG. 7A.

FIG. 7C is a top-down view of the first embodiment structure of FIG. 7A. The vertical plane A-A′ is the cut plane of the vertical cross-sectional view of FIG. 7A. The vertical plane B-B′ is the cut plane of the vertical cross-sectional view of FIG. 7B.

FIG. 8A is a vertical cross-sectional view of the first embodiment structure after formation of metal line structures according to an embodiment of the present disclosure.

FIG. 8B is a magnified vertical cross-sectional view of a region of the first embodiment structure of FIG. 8A.

FIG. 8C is a top-down view of the first embodiment structure of FIG. 8A. The vertical plane A-A′ is the cut plane of the vertical cross-sectional view of FIG. 8A. The vertical plane B-B′ is the cut plane of the vertical cross-sectional view of FIG. 8B.

FIG. 9 is a vertical cross-sectional view of an alternative configuration of the first embodiment structure after formation of peripheral via cavities according to an embodiment of the present disclosure.

FIG. 10A is a vertical cross-sectional view of the alternative configuration of the first embodiment structure after patterning the dielectric pad layer according to an embodiment of the present disclosure.

FIG. 10B is a magnified vertical cross-sectional view of a region of the second embodiment structure of FIG. 10A.

FIG. 11A is a vertical cross-sectional view of the alternative configuration of the first embodiment structure after formation of line cavities and vertical extension of the peripheral via cavities according to an embodiment of the present disclosure.

FIG. 11B is a magnified vertical cross-sectional view of a region of the second embodiment structure of FIG. 11A.

FIG. 12A is a vertical cross-sectional view of the alternative configuration of the first embodiment structure after formation of metal lines and integrated line and via structures according to an embodiment of the present disclosure.

FIG. 12B is a first magnified vertical cross-sectional view of a region of the second embodiment structure of FIG. 12A.

FIG. 12C is a second magnified vertical cross-sectional view of a region of the second embodiment structure of FIG. 12A.

FIG. 12D is a top-down view of the second embodiment structure of FIG. 12A. The vertical plane A-A′ is the cut plane of the vertical cross-sectional view of FIG. 12A. The vertical plane B-B′ is the cut plane of the vertical cross-sectional view of FIG. 12B. The vertical plane C-C′ is the cut plane of the vertical cross-sectional view of FIG. 12C.

FIG. 13 is a vertical cross-sectional view of the alternative configuration of the first embodiment structure after formation of additional metal interconnect structures according to an embodiment of the present disclosure.

FIGS. 14A-14F are sequential vertical cross-sectional views of a region of a second embodiment structure during formation of a resistive memory cell according to an embodiment of the present disclosure.

FIG. 14G is a vertical cross-sectional view of an alternative configuration of the second embodiment structure according to an embodiment of the present disclosure.

FIGS. 15A-15J are sequential vertical cross-sectional views of a region of a third embodiment structure during formation of a resistive memory cell according to an embodiment of the present disclosure.

FIG. 15K is a vertical cross-sectional view of an alternative configuration of the third embodiment structure according to an embodiment of the present disclosure.

FIGS. 16A-16F are sequential vertical cross-sectional views of a region of a fourth embodiment structure during formation of a resistive memory cell according to an embodiment of the present disclosure.

FIG. 16G is a vertical cross-sectional view of an alternative configuration of the fourth embodiment structure according to an embodiment of the present disclosure.

FIG. 17 is a flowchart that illustrates a sequence of processing steps for manufacturing a resistive memory device of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. Drawings are not drawn to scale. Elements with the same reference numerals refer to the same element, and are presumed to have the same material composition and the same thickness range unless expressly indicated otherwise. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For advanced resistive memory devices, the shapes and critical dimensions of a resistive memory cell are major factors influencing yield because of the sensitivity of the device leakage current and top electrode contact yield to the topography and dimensions of the top electrode. Various embodiments disclosed herein provide improvements in the topographical profile of a resistive memory cell to enhance manufacturing yield and device reliability. Embodiments of the present disclosure are directed to a resistive memory device in which erosion and corner rounding of a hard mask cap overlying a top electrode of a resistive memory cell are eliminated or reduced. A vertical cross-sectional profile of the resistive memory cell may be enhanced in a manner that decreases the taper angle of a sidewall of the resistive memory cell. For example, the taper angle of the resistive memory cell may be in a range from 70 degrees to 87 degrees. The area of the top surface of a top electrode of the resistive memory cell may be increased by a factor of 2 or more, providing a larger contact area for contact structures to be formed through a hard mask caping structure to the top surface of the top electrode. Contact yield for the top electrode may be markedly increased. The enhancement in the contact yield may be provided without adversely affecting device characteristics of the resistive memory cell, thereby enabling scaling of the resistive memory cell to technology nodes using smaller device dimensions.

In one embodiment, the lateral dimension of a bottom surface of a bottom electrode may be reduced while the lateral dimensions of a top surface of a hard mask plate and a top surface of top electrode may be increased such that peripheries of the hard mask plate and the top electrode may be formed outside areas of contoured surfaces of the bottom electrode and a memory material layer. The hard mask plate may be patterned without corner rounding, and the hard mask plate and the top electrode may be patterned with straight sidewalls having a small taper angle relative to a vertical direction. Thus, corner erosion may be avoided or minimized during patterning the top electrode, the memory material layer, and the bottom electrode during patterning of the resistive memory cell. Various embodiments disclosed herein may provide a large top electrode area that provides a large overlay tolerance for a top electrode contact structure relative to the pattern of the top electrode, and thus, may enhance the contact yield for the top electrode contact structure. Further, elimination or reduction of corner erosion during patterning the resistive memory cells allows enhanced uniformity for lateral dimensions of the resistive memory cells, thereby enhancing uniformity in the device characteristics. Aspects of various embodiments of the present disclosure are described with reference to accompanying drawings herebelow.

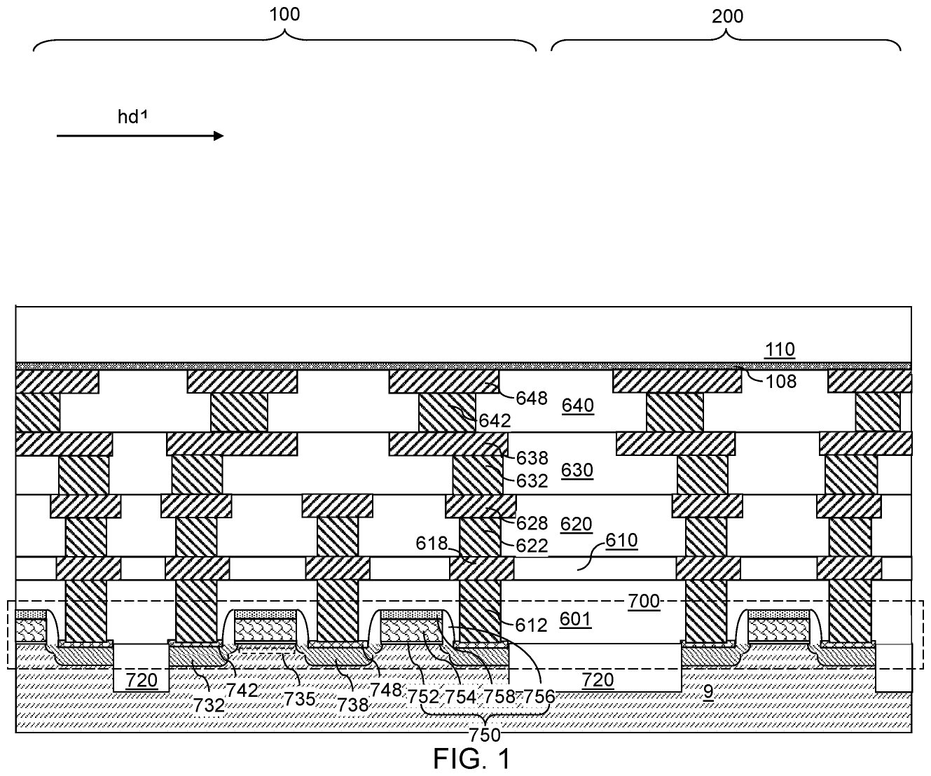

FIG. 1 is a vertical cross-sectional view of a first embodiment structure along a vertical plane that is parallel to a first horizontal direction hd1 after formation of complementary metal-oxide-semiconductor (CMOS) transistors, metal interconnect structures formed within lower-level dielectric material layers, and a connection-via-level dielectric layer according to an embodiment of the present disclosure. The first embodiment structure includes complementary metal-oxide-semiconductor (CMOS) transistors and metal interconnect structures formed in dielectric material layers. Specifically, the first embodiment structure includes a substrate 9, which may be a semiconductor substrate such as a commercially available silicon wafer. Shallow trench isolation structures 720 including a dielectric material such as silicon oxide may be formed in an upper portion of the substrate 9. Suitable doped semiconductor wells, such as p-type wells and n-type wells, may be formed within each area that may be laterally enclosed by a portion of the shallow trench isolation structures 720. Field effect transistors may be formed over the top surface of the substrate 9. For example, each field effect transistor may include a source region 732, a drain region 738, a semiconductor channel 735 that includes a surface portion of the substrate 9 extending between the source region 732 and the drain region 738, and a gate structure 750. Each gate structure 750 may include a gate dielectric 752, a gate electrode 754, a gate cap dielectric 758, and a dielectric gate spacer 756. A source-side metal-semiconductor alloy region 742 may be formed on each source region 732, and a drain-side metal-semiconductor alloy region 748 may be formed on each drain region 738. While planar field effect transistors are illustrated in the drawings, embodiments are expressly contemplated herein in which the field effect transistors may additionally or alternatively include fin field effect transistors (FinFET), gate-all-around field effect (GAA FET) transistors, or any other type of field effect transistors (FETs).

The first embodiment structure may include a memory array region 100 in which an array of memory elements may be subsequently formed, and a peripheral region 200 in which logic devices that support operation of the array of memory elements may be formed. In one embodiment, devices (such as field effect transistors) in the memory array region 100 may include bottom electrode access transistors that provide access to bottom electrodes of memory cells to be subsequently formed. Upper electrode access transistors that provide access to upper electrodes of memory cells to be subsequently formed may be formed in the peripheral region 200 at this processing step. Devices (such as field effect transistors) in the peripheral region 200 may provide functions that may be needed to operate the array of memory cells to be subsequently formed. Specifically, devices in the peripheral region may be configured to control the programming operation, the erase operation, and the sensing (read) operation of the array of memory cells. For example, the devices in the peripheral region may include a sensing circuitry and/or a upper electrode bias circuitry. The devices formed on the top surface of the substrate 9 may include complementary metal-oxide-semiconductor (CMOS) transistors and optionally additional semiconductor devices (such as resistors, diodes, capacitors, etc.), and are collectively referred to as CMOS circuitry 700.

Various metal interconnect structures formed within dielectric material layers may be subsequently formed over the substrate 9 and the devices (such as field effect transistors). The dielectric material layers may include, for example, a contact-level dielectric material layer 601, a first metal-line-level dielectric material layer 610, a second line-and-via-level dielectric material layer 620, a third line-and-via-level dielectric material layer 630, and a fourth line-and-via-level dielectric material layer 640. The metal interconnect structures may include device contact via structures 612 formed in the contact-level dielectric material layer 601 and contact a respective component of the CMOS circuitry 700, first metal line structures 618 formed in the first metal-line-level dielectric material layer 610, first metal via structures 622 formed in a lower portion of the second line-and-via-level dielectric material layer 620, second metal line structures 628 formed in an upper portion of the second line-and-via-level dielectric material layer 620, second metal via structures 632 formed in a lower portion of the third line-and-via-level dielectric material layer 630, third metal line structures 638 formed in an upper portion of the third line-and-via-level dielectric material layer 630, third metal via structures 642 formed in a lower portion of the fourth line-and-via-level dielectric material layer 640, and fourth metal line structures 648 formed in an upper portion of the fourth line-and-via-level dielectric material layer 640. In one embodiment, the second metal line structures 628 may include source lines that are connected a source-side power supply for an array of memory elements. The voltage provided by the source lines may be applied to the bottom electrodes through the access transistors provided in the memory array region 100.

Each of the dielectric material layers (601, 610, 620, 630, 640) may include a dielectric material such as undoped silicate glass, a doped silicate glass, organosilicate glass, amorphous fluorinated carbon, porous variants thereof, or combinations thereof. Each of the metal interconnect structures (612, 618, 622, 628, 632, 638, 642, 648) may include at least one conductive material, which may be a combination of a metallic liner layer (such as a metallic nitride or a metallic carbide) and a metallic fill material. Each metallic liner layer may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 622 and the second metal line structures 628 may be formed as integrated line and via structures by a dual damascene process, the second metal via structures 632 and the third metal line structures 638 may be formed as integrated line and via structures, and/or the third metal via structures 642 and the fourth metal line structures 648 may be formed as integrated line and via structures. While the present disclosure is described using an embodiment in which an array of memory cells formed over the fourth line-and-via-level dielectric material layer 640, embodiments are expressly contemplated herein in which the array of memory cells may be formed at a different metal interconnect level.

The dielectric material layers (601, 610, 620, 630, 640) may be located at a lower level relative to an array of memory cells to be subsequently formed. As such, the dielectric material layers (601, 610, 620, 630, 640) are herein referred to as lower-level dielectric material layers, i.e., dielectric material layer located at lower levels relative to the array of memory cells to be subsequently formed. The metal interconnect structures (612, 618, 622, 628, 632, 638, 642, 648) are herein referred to lower-level metal interconnect structures. A subset of the metal interconnect structures (612, 618, 622, 628, 632, 638, 642, 648) includes lower-level metal lines (such as the fourth metal line structures 648) that are formed in the lower-level dielectric layers and having top surfaces within a horizontal plane including a topmost surface of the lower-level dielectric layers. Generally, the total number of metal line levels within the lower-level dielectric layers (601, 610, 620, 630, 640) may be in a range from 1 to 10.

A dielectric cap layer 108 and a lower connection-via-level dielectric layer 110 may be sequentially formed over the metal interconnect structures and the dielectric material layers. The dielectric cap layer 108 and the lower connection-via-level dielectric layer 110 may be additional lower-level dielectric material layers. For example, the dielectric cap layer 108 may be formed on the top surfaces of the fourth metal line structures 648 and on the top surface of the fourth line-and-via-level dielectric material layer 640. The dielectric cap layer 108 includes a dielectric capping material that may protect underlying metal interconnect structures such as the fourth metal line structures 648. In one embodiment, the dielectric cap layer 108 may include a material that may provide high etch resistance, i.e., a dielectric material and also may function as an etch stop material during a subsequent anisotropic etch process that etches the lower connection-via-level dielectric layer 110. For example, the dielectric cap layer 108 may include silicon carbide or silicon nitride, and may have a thickness in a range from 5 nm to 30 nm, although lesser and greater thicknesses may also be used.

The lower connection-via-level dielectric layer 110 may include any material that may be used for the dielectric material layers (601, 610, 620, 630, 640). For example, the lower connection-via-level dielectric layer 110 may include undoped silicate glass or a doped silicate glass deposited by decomposition of tetraethylorthosilicate (TEOS). The thickness of the lower connection-via-level dielectric layer 110 may be in a range from 50 nm to 200 nm, although lesser and greater thicknesses may also be used. The dielectric cap layer 108 and the lower connection-via-level dielectric layer 110 may be formed as planar blanket (unpatterned) layers having a respective planar top surface and a respective planar bottom surface that extends throughout the memory array region 100 and the peripheral region 200.

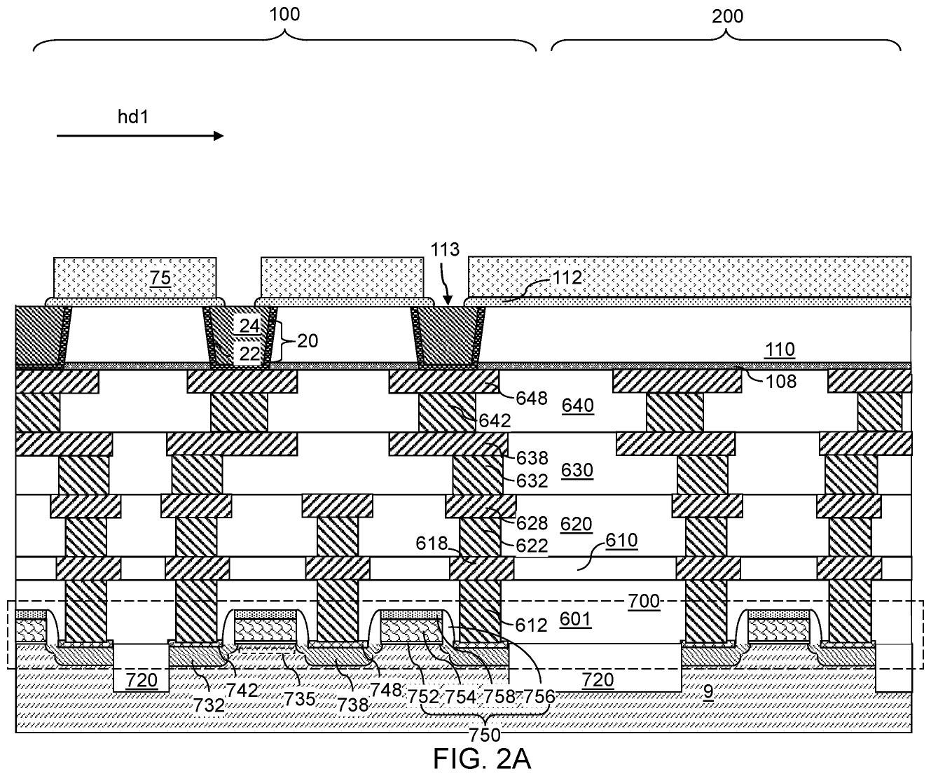

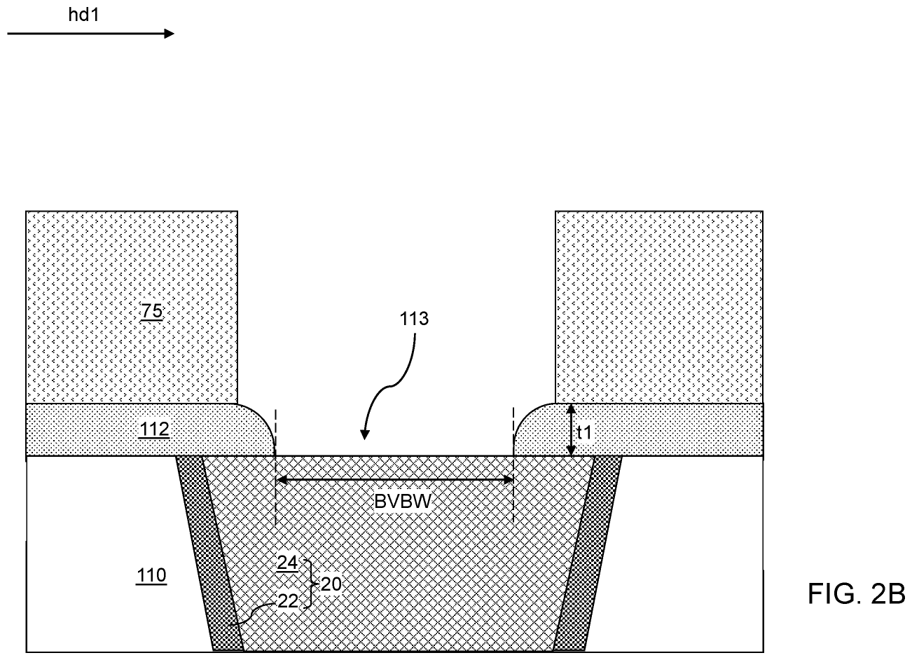

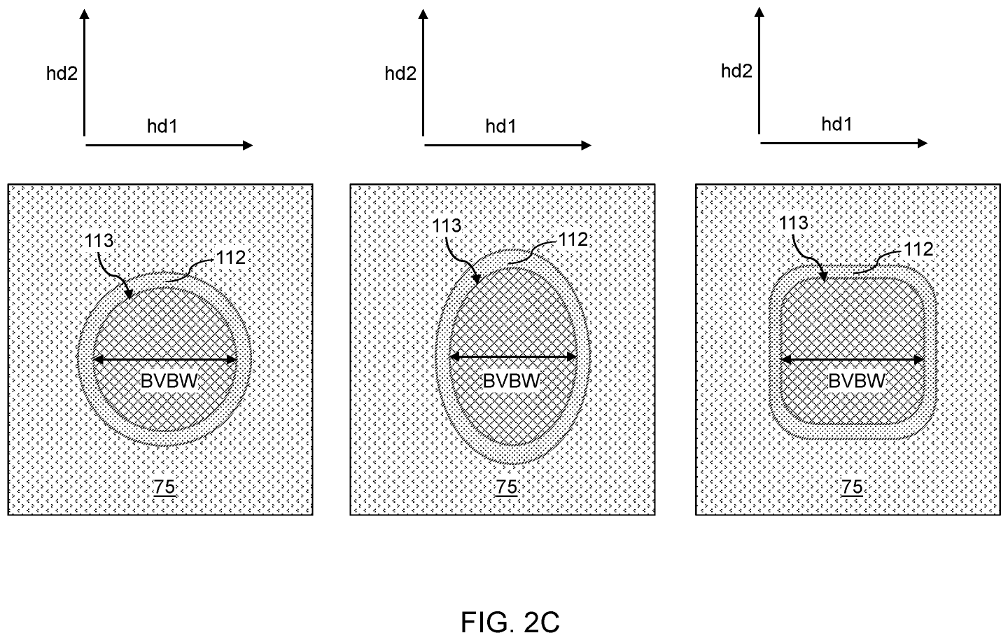

Referring to FIGS. 2A-2C, via cavities may be formed through the lower connection-via-level dielectric layer 110 and the dielectric cap layer 108 of the first embodiment structure. For example, a photoresist layer (not shown) may be applied over the lower connection-via-level dielectric layer 110 and may be patterned to form opening within areas of the memory array region 100 that overlie a respective one of the fourth metal line structures 648. An anisotropic etch may be performed to transfer the pattern in the photoresist layer through the lower connection-via-level dielectric layer 110 and the dielectric cap layer 108. The via cavities formed by the anisotropic etch process are herein referred to as lower-electrode-contact via cavities because bottom electrode connection via structures are subsequently formed in the lower-electrode-contact via cavities. The lower-electrode-contact via cavities may have tapered sidewalls having a taper angle (within respective to a vertical direction) in a range from 1 degree to 10 degrees. A top surface of a fourth metal line structure 648 may be physically exposed at the bottom of each lower-electrode-contact via cavity. The photoresist layer may be subsequently removed, for example, by ashing.

A metallic barrier layer may be formed as a material layer. The metallic barrier layer may cover physically exposed top surfaces of the fourth metal line structures 648, tapered sidewalls of the lower-electrode-contact via cavities, and the top surface of the lower connection-via-level dielectric layer 110 without any hole therethrough. The metallic barrier layer may include a conductive metallic nitride such as TiN, TaN, and/or WN. Other suitable materials within the contemplated scope of disclosure may also be used. The thickness of the metallic barrier layer may be in a range from 3 nm to 20 nm, although lesser and greater thicknesses may also be used.

A metallic fill material such as tungsten or copper may be deposited in remaining volumes of the lower-electrode-contact via cavities. Portions of the metallic fill material and the metallic barrier layer that overlie the horizontal plane including the topmost surface of the lower connection-via-level dielectric layer 110 may be removed by a planarization process such as chemical mechanical planarization to form. Each remaining portion of the metallic fill material located in a respective via cavity comprises a metallic via fill material portion 24. Each remaining portion of the metallic barrier layer in a respective via cavity comprises a metallic barrier layer 22. Each combination of a metallic barrier layer 22 and a metallic via fill material portion 24 that fills a via cavity constitutes a bottom connection via structure 20. An array of bottom connection via structures 20 may be formed in the lower connection-via-level dielectric layer 110 on underlying metal interconnect structures (i.e., 612, 618, 622, 628, 632, 638, 642, 648). The array of bottom connection via structures 20 may contact top surfaces of a subset of the fourth metal line structures 648. Generally, the array of bottom connection via structures 20 contacts top surfaces of a subset of lower-level metal lines located at the topmost level of the lower-level dielectric layers (601, 610, 620, 630, 640). Generally, first metal interconnect structured (such as bottom connection via structures 20) formed in a first dielectric material layer (such as a lower connection-via-level dielectric layer 110) may be formed over the substrate.

An etch-stop dielectric layer 112 may be formed over the first metal interconnect structure (such as the bottom connection via structures 20) in the first dielectric material layer (such as the lower connection-via-level dielectric layer 110). The etch-stop dielectric layer 112 comprises a dielectric material that may effectively function as an etch-stop material layer. For example, the etch-stop dielectric layer 112 may comprise a dielectric material such as silicon carbide nitride, silicon carbide oxide, silicon carbide, silicon nitride, silicon oxynitride, a dielectric metal oxide such as aluminum oxide, lanthanum oxide, or titanium oxide, or a combination thereof. The thickness of the etch-stop dielectric layer 112, which is herein referred to as a first thickness t1, may be in a range from 10 nm to 60 nm, such as from 20 nm to 40 nm, although lesser and greater thicknesses may also be used.

A photoresist layer 75 may be applied over the etch-stop dielectric layer 112, and may be lithographically patterned to form an array of openings therein. The areas of the openings in the photoresist layer 75 may be entirely within the areas of the top surfaces of the bottom connection via structures 20. An anisotropic etch process may be performed to transfer the pattern of the openings in the photoresist layer 75 through the etch-stop dielectric layer 112. In one embodiment, the chemistry of the anisotropic etch process may be selected to generate a polymer material on physically exposed sidewalls of the etch-stop dielectric layer 112. Additionally or alternatively, the openings in the photoresist layer 75 may be collaterally widened during the anisotropic etch process. Openings 113 may be formed through the etch-stop dielectric layer 112 such that each opening 113 may have a respective tapered annular sidewall. In one embodiment, a tapered annular sidewall of an opening 113 may have a convex vertical cross-sectional profile.

In one embodiment, each opening 113 within a two-dimensional array of openings 113 through the etch-stop dielectric layer 112 may have a same shape and a same size. In one embodiment, each opening 113 may have a first width (which is herein referred to as bottom-electrode via bottom width BVBW) along the first horizontal direction hd1 through the etch-stop dielectric layer 112. The first width of each opening 113 along the first horizontal direction hd1 may be measured at the bottom of the respective opening 113. A second horizontal direction hd2 may be perpendicular to the first horizontal direction hd1.

Generally, each opening through the etch-stop dielectric layer 112 may have any closed two-dimensional shape in a plan view, such as a top-down view, along the vertical direction (such as the top-down views shown in FIG. 2C). In ne embodiment, each opening 113 in the etch-stop dielectric layer 112 has a shape of a circle, an oval, or a rounded rectangle. In one embodiment, the first width (such as a bottom-electrode via bottom width BVBW) may be a diameter, a minor axis, or a distance between a pair of parallel segments. The area of each opening 113 through the etch-stop dielectric layer 112 may be located entirely within the area of a periphery of a top surface of a respective underlying bottom connection via structure 20. In one embodiment, the bottom-electrode via bottom width BVBW may be in a range from 50 nm to 200 nm, although lesser and greater dimensions may also be used.

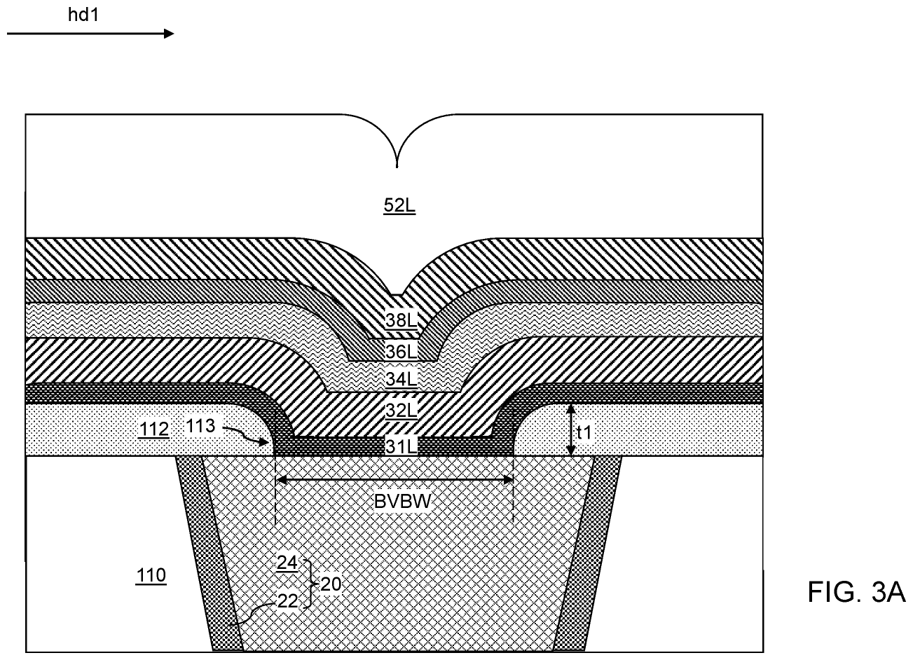

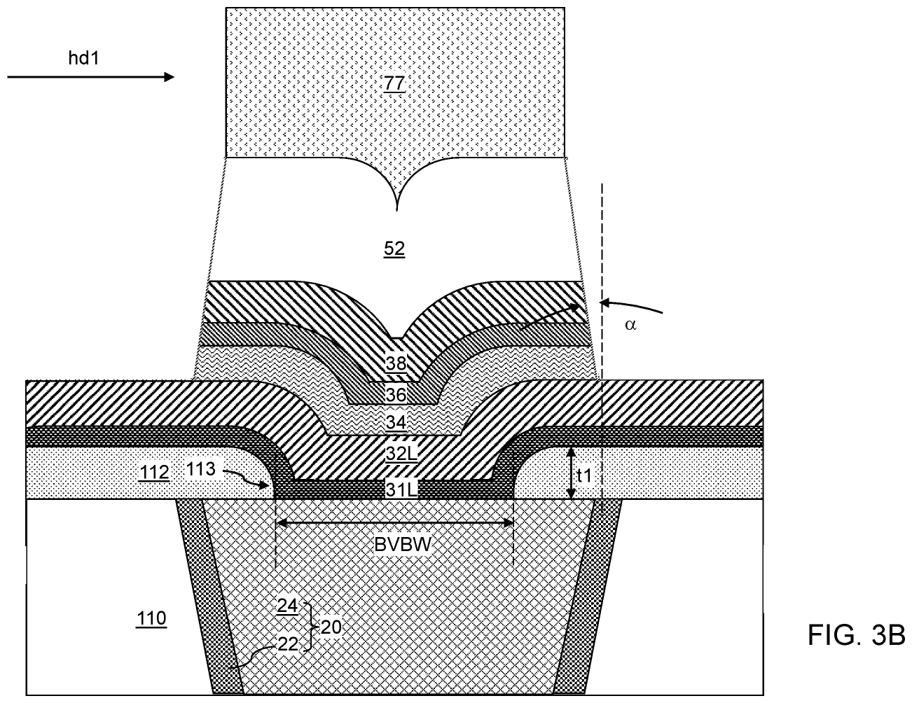

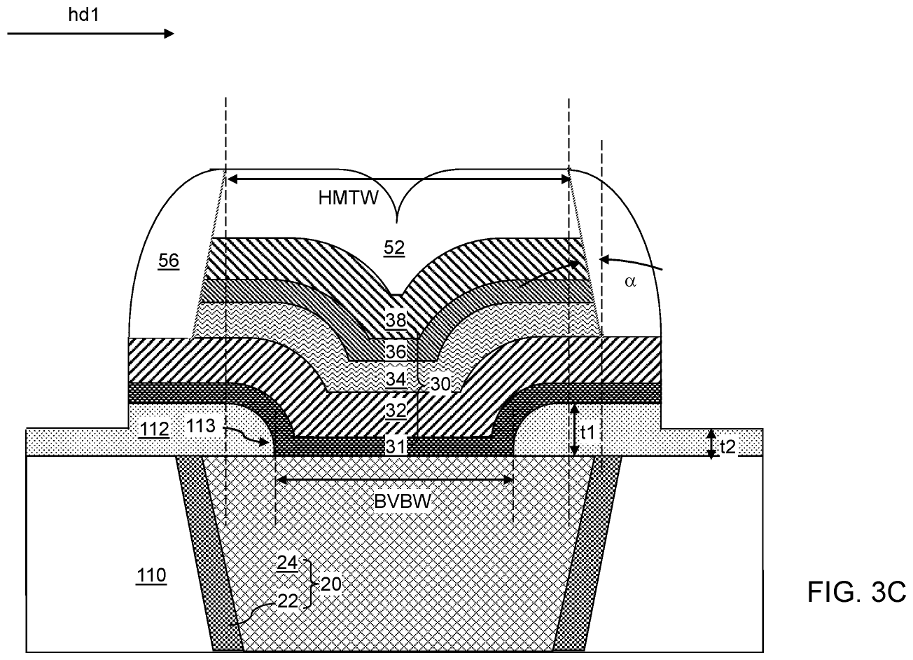

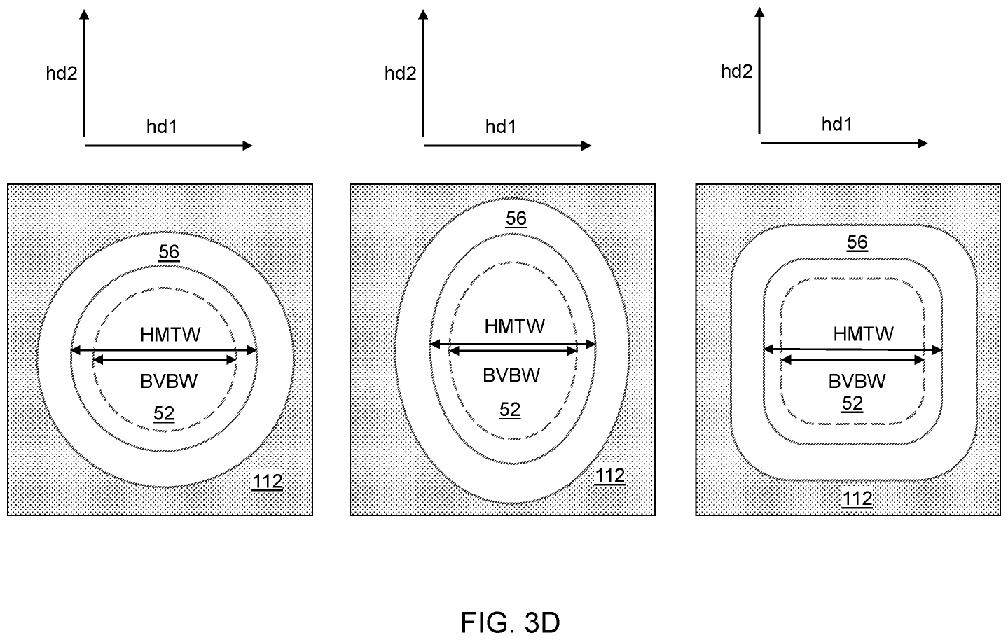

FIGS. 3A-3C are sequential vertical cross-sectional views of a region of the first embodiment structure during formation of a resistive memory cell 30 according to an embodiment of the present disclosure. FIG. 3D illustrate top-down views of various configurations of the first embodiment structure of FIG. 3C.

Referring to FIG. 3A, a layer stack including a bottom metallic barrier material layer 31L, a bottom metal layer 32L, a continuous memory material layer 34L, an optional capping material layer 36L, a top electrode material layer 38L, and a hard mask material layer 52L may be deposited over physically exposed surfaces of the bottom connection via structures 20 and over the etch-stop dielectric layer 112. The combination of the bottom metallic barrier material layer 31L and the bottom metal layer 32L is subsequently used to pattern bottom electrodes, and thus, is herein referred to as a bottom electrode material layer (31L, 32L). Each volume of the openings 113 in the etch-stop dielectric layer 112 may be filled with a respective portion of the bottom electrode material layer (31L, 32L).

In one embodiment, the bottom metallic barrier material layer 31L may include at least one conductive metallic nitride material such as TaN, TiN, or WN. The bottom metallic barrier material layer 31L may have a thickness in a range from 5 nm to 100 nm, such as from 10 nm to 30 nm, although lesser and greater thicknesses may also be used. In one embodiment, the bottom metal layer 32L may comprise, and/or may consist essentially of, a metal having a melting point higher than 2,000 degrees Celsius. For example, the bottom metal layer 32L may comprise, and/or may consist of, hafnium, ruthenium, iridium, niobium, molybdenum, tantalum, osmium, rhenium, or tungsten. Other suitable metal materials may be within the contemplated scope of disclosure. In one embodiment, the bottom metal layer 32L may include a group 8 element (such as ruthenium or osmium) or a group 9 element (such as rhodium or iridium). Generally, use of a metal having a high melting point for the bottom metal layer 32L may be advantageous for the purpose of reducing, or eliminating, atoms of the first metal within bottom electrodes during operation of resistive memory cells. In one embodiment, the bottom metal layer 32L may include ruthenium. The bottom metal layer 32L may be deposited by physical vapor deposition or chemical vapor deposition. The thickness of the bottom metal layer 32L may be in a range from 10 nm to 100 nm, such as from 20 nm to 50 nm and/or from 6 nm to 20 nm, although lesser and greater thicknesses may also be used.

The continuous memory material layer 34L comprises a resistive memory material, which refers to a material that provides at least two different resistive states providing different electrical resistance. Generally, the resistive memory material may be any type of resistive memory material known in the art. In one embodiment, the resistive memory material may comprise a filament-forming metal oxide material which provides a higher conductivity upon formation of conductive filaments therein (such as hafnium oxide, titanium oxide, niobium pentoxide, germanium telluride, silver sulfate, zinc oxide, vanadium oxide, tantalum oxide, zirconium oxide, etc.). In one embodiment, the resistive memory material may comprise a phase change memory material containing a chalcogenide glass (such as an alloy of germanium, antimony, and tellurium, and optionally additional additives). In one embodiment, the resistive memory material may comprise a conductive bridge-forming material in which conductive bridges may be formed or ruptured (such as silver, copper, silver sulfide, mixed ionic-electronic conductor materials (e.g., yttria-stabilized zirconia), etc.). In one embodiment, the resistive memory material may comprise an organic polymer material that may provide at least two different resistive states. In one embodiment, the resistive memory material may comprise a perovskite-based material that may provide at least two different resistive states. In one embodiment, the resistive memory material may comprise a two-dimensional material such as molybdenum disulfide (MoS₂) that may provide at least two different resistive states. In one embodiment, the resistive memory material may comprise an organic-inorganic hybrid resistive memory material that may provide at least two different resistive states. In one embodiment, the resistive memory material may comprise a rare earth oxide resistive memory material that may provide at least two different resistive states.

In one embodiment, the continuous memory material layer 34L comprises, and/or consists essentially of, a conductive-filament-forming dielectric oxide of at least one transition metal. A conductive-filament-forming dielectric oxide refers to a dielectric oxide that may form conductive filaments upon application of an electrical field therethrough. Exemplary conductive-filament-forming dielectric oxides include hafnium oxide, zirconium oxide, titanium oxide, hafnium zirconium oxide, and strontium cobalt oxide. The electrical resistivity of the continuous memory material layer 34L along the thickness direction (e.g., along the vertical direction) may change by at least one order of magnitude, such as 2 to 6 orders of magnitude, upon formation of conductive filaments therein through application of an electrical bias voltage. In embodiments in which the continuous memory material layer 34L comprises hafnium oxide, a vertical electrical field having a magnitude of about 2.6 MV/cm may be used to form conductive filaments therein. An electrical field along the opposite polarity and having a lesser magnitude may be applied to remove the conductive filaments from within the continuous memory material layer 34L.

The continuous memory material layer 34L may be deposited by atomic layer deposition, chemical vapor deposition, or physical vapor deposition. For example, if the continuous memory material layer 34L comprises hafnium oxide, an atomic layer deposition using a hafnium-containing precursor gas (such as hafnium tetrachloride) and an oxygen source gas (such as H₂O, O₂, or O₃) may be alternately flowed into a process chamber containing the first embodiment structure to deposit the continuous memory material layer 34L. The thickness of the continuous memory material layer 34L may be in a range from 1 nm to 50 nm, such as from 3 nm to 20 nm and/or from 6 nm to 10 nm, although lesser and greater thicknesses may also be used.

The capping material layer 36L, in embodiments in which the capping material layer 36L is present, comprises a capping material that may enhance electrical characteristics of the memory material layer in the continuous memory material layer 34L. In embodiments in which the capping material layer 36L is used, the capping material layer 36L may be used as a diffusion barrier layer and may be used to modulate the switching characteristics of the resistive memory material in the continuous memory material layer 34L and/or to enhance the endurance and the device stability of resistive memory devices to be subsequently formed. In one embodiment, the capping material layer 36L may comprise a conductive metallic nitride material such as TiN, TaN, WN, and/or MON, a metal oxide material such as ruthenium oxide or iridium oxide, a metal silicide material such as titanium silicide or tungsten silicide, a thin layer of diamond-like carbon, and/or other suitable liner materials.

The top electrode material layer 38L may comprise any material that may be used for the bottom metal layer 32L. The thickness of the top electrode material layer 38L may be in a range from 10 nm to 100 nm, such as from 20 nm to 50 nm and/or from 6 nm to 20 nm, although lesser and greater thicknesses may also be used.

The hard mask material layer 52L comprises a dielectric material that is suitable as a hard mask material. For example, the hard mask material layer 52L may comprise, and/or may consist essentially of, silicon oxynitride, silicon nitride, silicon carbide nitride, silicon carbide oxide, and/or a dielectric metal oxide. The hard mask material layer 52L may be formed by chemical vapor deposition (CVD) and/or atomic layer deposition (ALD). The thickness of the hard mask material layer 52L may be in a range from 30 nm to 200 nm, and/or from 60 nm to 120 nm, although lesser and greater thicknesses may also be used. The hard mask material layer 52L may comprise a two-dimensional array of downward-protruding portions that fill a two-dimensional array of divots in the top surface of the top electrode material layer 38L.

Referring to FIG. 3B, a photoresist layer may be applied over the top surface of the hard mask material layer 52L, and may be lithographically patterned to form a two-dimensional array of patterned photoresist material portions 77. According to an aspect of the present disclosure, each patterned photoresist material portion 77 may have a respective sidewall that is located entirely within the area of a periphery of an underlying bottom connection via structure 20, and is located entirely outside the area of an opening 113 in an underlying portion of the etch-stop dielectric layer 112. In one embodiment, each patterned photoresist material portion 77 has a second width has a second width along the first horizontal direction hd1 which is greater than the first width (such as a bottom-electrode via bottom width BVBW), and is less than the lateral dimension of the top surface of an underlying bottom connection via structure 20. In one embodiment, each patterned photoresist material portion 77 covers an entirety of an area of a respective underlying opening 113 in the etch-stop dielectric layer 112 in a plan view, i.e., a view along the vertical direction.

A first anisotropic etch process may be performed to transfer the pattern of the two-dimensional array of patterned photoresist material portions 77 through the hard mask material layer 52L, the top electrode material layer 38L, the optional capping material layer 36L, and the continuous memory material layer 34L using the patterned photoresist material portions 77 as an etch mask. The first anisotropic etch process may comprise a sequence of anisotropic etch steps having a respective etch chemistry and providing sequential etching of the materials of the hard mask material layer 52L, the top electrode material layer 38L, the optional capping material layer 36L, and the continuous memory material layer 34L. A patterned stack of a memory material layer 34, an optional capping material plate 36, a top electrode 38, and a hard mask plate 52 may be formed underneath each patterned photoresist material portion 77. Each hard mask plate 52 is a patterned portion of the hard mask material layer 52L. Each top electrode 38 is a patterned portion of the top electrode material layer 38L. Each capping material plate 36 is a patterned portion of the capping material layer 36L. Each memory material layer 34 is a patterned portion of the continuous memory material layer 34L.

According to an aspect of the present disclosure, the first anisotropic etch process may use an etch chemistry that minimizes erosion of the hard mask plates 52. In this embodiment, the first anisotropic etch process may use a hydrogen-free etchant such as CF₄ or SF₆ to sustain a substantially vertical sidewall profile for the hard mask plates 52. A tapered surface may extend straight from the periphery of the top surface of a hard mask plate 52 at least to a top surface of the bottom electrode material layer (31L, 32L) at a taper angle α with respect to a vertical direction. The taper angle α may be in a range from 5 degrees to 20 degrees, such as from 5 degrees to 15 degrees. The array of patterned photoresist material portions 77 may be subsequently removed, for example, by ashing. A planar horizontal portion of the top surface of the bottom electrode material layer (31L, 32L) may be physically exposed after the first anisotropic etch process.

Referring to FIGS. 3C and 3D, a dielectric material such as silicon nitride, silicon oxide, silicon carbide nitride, or silicon oxynitride may be conformally deposited over a two-dimensional array of stacks of a memory material layer 34, an optional capping material plate 36, a top electrode 38, and a hard mask plate 52 to form a conformal dielectric material layer. A second anisotropic etch process may be performed to remove horizontally-extending portions of the conformal dielectric material layer. Each remaining vertically-extending portion of the conformal dielectric material layer constitutes a dielectric spacer 56. The second anisotropic etch process may be continued to etch physically exposed portions of the bottom electrode material layer (31L, 32L) using a combination of a two-dimensional array of hard mask plates 52 and a two-dimensional array of dielectric spacers 56 as an etch mask. The second anisotropic etch process may collaterally etch unmasked portions of the etch-stop dielectric layer 112. Etched portions of the etch-stop dielectric layer 112 may have a second thickness t2 which is less than the first thickness t1.

Each patterned portion of the bottom electrode material layer (31L, 32L) constitutes a bottom electrode (31, 32). Each bottom electrode (31, 32) may comprise a combination of a bottom metallic barrier layer 31 and a bottom metal plate 32. The bottom metallic barrier layer 31 may be a patterned portion of the bottom metallic barrier material layer 31L, and the bottom metal plate 32 may be a patterned portion of the bottom metal layer 32L. Each dielectric spacer 56 may have a tubular configuration with a straight tapered sidewall and a contoured outer sidewall. Each dielectric spacer 56 may be topologically homeomorphic to a torus, i.e., may be continuously deformed into a torus without creating a new hole and without destroying any existing hole.

Each dielectric spacer 56 may have a bottom surface that contacts a planar surface segment of a top surface of an underlying bottom electrode (31, 32). The bottom surface of each dielectric spacer 56 may have an inner periphery and an outer periphery that is laterally offset outward from the inner periphery by a uniform lateral offset distance, which is the lateral thickness of the dielectric spacer 56 at the horizontal plane including the bottom surface. The bottom periphery of the outer sidewall of each dielectric spacer 56 may coincide with a periphery of the top surface of a respective underlying bottom electrode (31, 32). Each dielectric spacer 56 may be in contact with an entirety of the tapered surface of a stack of a hard mask plate 52, a top electrode 38, a capping material plate 36, and a memory material layer 34. Each dielectric spacer 56 may laterally surround the stack of the hard mask plate 52, the top electrode 38, the capping material plate 36, and the memory material layer 34

In one embodiment, each dielectric spacer 56 may have an annular bottom surface that is in contact with an annular surface segment of a top surface of an underlying bottom electrode (31, 32). As used herein, an annular surface refers to a surface having an inner periphery and an outer periphery that is laterally offset outward from the inner periphery by a uniform lateral offset distance. In one embodiment, each bottom electrode (31, 32) may comprise a top surface that includes an annular top surface segment and a central recessed horizontal surface segment that underlies a downward-protruding portion of an overlying memory material layer 34. According to an aspect of the present disclosure, the lateral extent of the central recessed horizontal surface segment along the first horizontal direction hd1 is less than a first width (such as a bottom-electrode via bottom width BVBW) of an underlying opening 113 in the etch-stop dielectric layer 112.

The second anisotropic etch process may collaterally reduce the thickness of the hard mask plate 52. The thickness of a horizontally-extending portion of each hard mask plate 52 may be in a range from 25 nm to 180 nm, and/or from 40 nm to 100 nm, although lesser and greater thicknesses may also be used. The periphery of the top surface of each hard mask plate 52 may have a second width along the first horizontal direction hd1, which is herein referred to as a hard mask top width HMTW. The second width is greater than the first width (such as a bottom-electrode via bottom width BVBW).

Generally, the top electrode material layer 38L, the continuous memory material layer 34L, and the bottom electrode material layer (31L, 32L) may be patterned into a two-dimensional array of resistive memory cells 30. Each resistive memory cell 30 comprises a top electrode 38, an optional capping material plate 36, a memory material layer 34, and a bottom electrode (31, 32). In one embodiment, each bottom electrode (31, 32) comprises a plate portion overlying the etch-stop dielectric layer 112 and a via portion located within the opening 113 in the etch-stop dielectric layer 112. In other words, the via portion vertically extends downward into a respective opening 113 in the etch-stop dielectric layer 112. In one embodiment, the memory material layer 34 overlies the bottom electrode (31, 32) and is configured to provide at least two states having different electrical resistance. In one embodiment, within each resistive memory cell 30, the memory material layer 34 is located entirely within an area of a top surface of an underlying bottom connection via structure 20 (which is a metallic via structure) in a plan view upon patterning of the memory material layer 34. The top electrode 38 overlies the memory material layer 34.

In one embodiment, the etch-stop dielectric layer 112 comprises an annular portion that laterally surrounds an opening 113 in the etch-stop dielectric layer 112 and having a first thickness t1, and a planar layer portion having a second thickness t2 that is less than the first thickness t1 and laterally spaced from the opening 113 by the annular portion. Thus, the annular portion has the first thickness t1 and includes an opening 113 therethrough, and the planar layer portion has a second thickness t2 that is less than the first thickness t1 and is laterally spaced from the opening 113 by the annular portion.

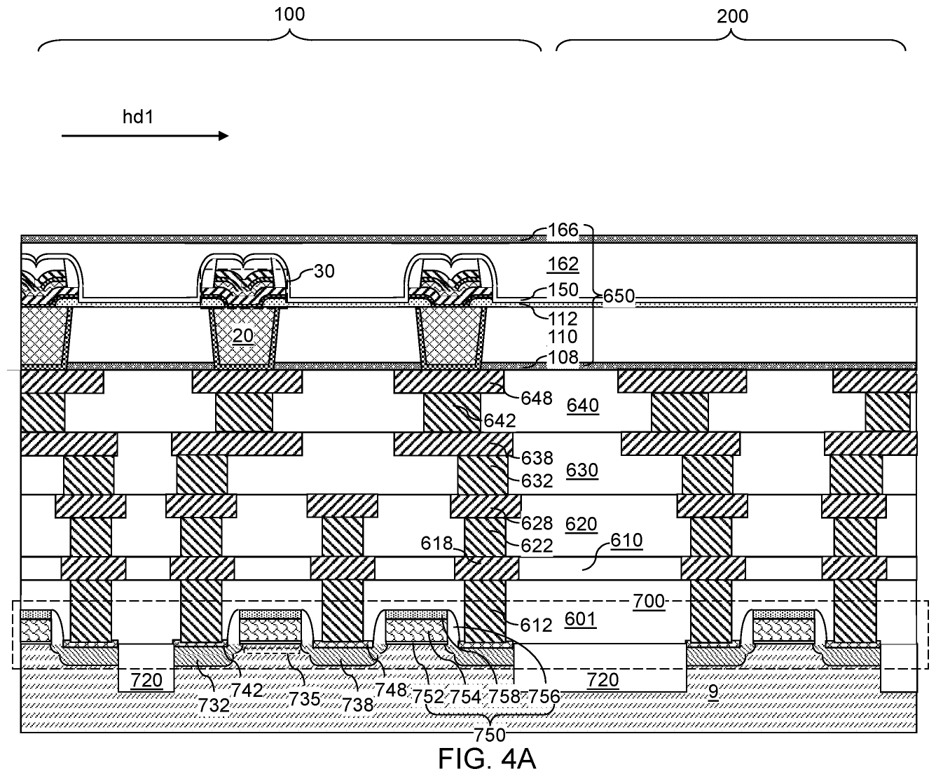

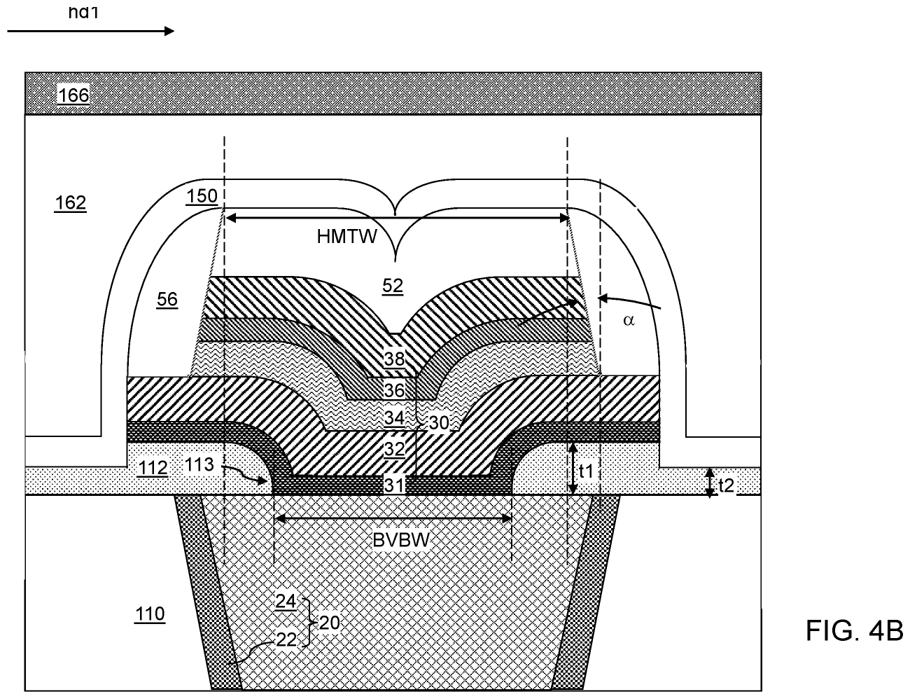

Referring to FIGS. 4A and 4B, a dielectric capping layer 150 may be optionally deposited conformally over the two-dimensional array of resistive memory cells 30, a two-dimensional array of hard mask plates 52, and a two-dimensional array of dielectric spacers 56. The dielectric capping layer 150 may include a non-porous dielectric material such as undoped silicate glass, a doped silicate glass, silicon oxynitride, or silicon nitride. The dielectric capping layer 150 may be deposited by a conformal deposition process such as a chemical vapor deposition process. The thickness of the dielectric capping layer 150 may be in a range from 4 nm to 100 nm, such as from 8 nm to 50 nm, although lesser and greater thicknesses may also be used.

The dielectric capping layer 150 laterally surrounds the two-dimensional array of resistive memory cells 30. The dielectric capping layer 150 contacts cylindrical sidewalls of the etch-stop dielectric layer 112 connecting a periphery of a top surface of a respective annular portion of the etch-stop dielectric layer 112 and a respective periphery of a top surface of the planar layer portion of the etch-stop dielectric layer 112 having the second thickness t2. The dielectric capping layer 150 may contacts a sidewall of each bottom electrode (31, 32), and may contact the top surface of each hard mask plate 52.

A dielectric material layer may be subsequently deposited over the dielectric capping layer 150. This dielectric material layer is herein referred to as a memory-level dielectric layer 162. In one embodiment, the memory-level dielectric layer 162 may include a low-k dielectric material having a dielectric constant less than 3.9. For example, the memory-level dielectric layer 162 may include non-porous organosilicate glass or porous organosilicate glass. Optionally, the top surface of the memory-level dielectric layer 162 may be planarized. The thickness of the memory-level dielectric layer 162 as measured above the topmost surfaces of the dielectric capping layer 150 overlying the resistive memory cells 30 may be in a range from 50 nm to 300 nm, such as from 100 nm to 200 nm, although lesser and greater thicknesses may also be used.

The memory-level dielectric layer 162 is formed around, and over, the two-dimensional array of resistive memory cells 30. The memory-level dielectric layer 162 laterally surrounds the bottom electrode (31, 32), the memory material layer 34, and the top electrode 38 of each resistive memory cell 30. The memory-level dielectric layer 162 overlies the horizontally-extending portion of the dielectric capping layer 150, and laterally surrounding each portion of the dielectric capping layer 150 that protrudes above the horizontally-extending portion of the dielectric capping layer 150.

A dielectric pad layer 166 may be deposited over the memory-level dielectric layer 162. The dielectric pad layer 166 comprises a dielectric material that may be used as a planarization stopping layer during a subsequent chemical mechanical polishing process. In one embodiment, the dielectric pad layer 166 may comprise silicon nitride, silicon carbide nitride, or silicon carbide oxide. The thickness of the dielectric pad layer 166 may be in a range from 20 nm to 100 nm, such as from 30 nm to 60 nm, although lesser and greater thicknesses may also be used.

The combination of all dielectric material layers overlying the fourth line-and-via-level dielectric material layer 640 constitutes a fifth line-and-via-level dielectric material layer 650. In one embodiment, the fifth line-and-via-level dielectric material layer 650 may comprise, from bottom to top, the dielectric cap layer 108, the lower connection-via-level dielectric layer 110, the etch-stop dielectric layer 112, the dielectric capping layer 150, the memory-level dielectric layer 162, and the dielectric pad layer 166.

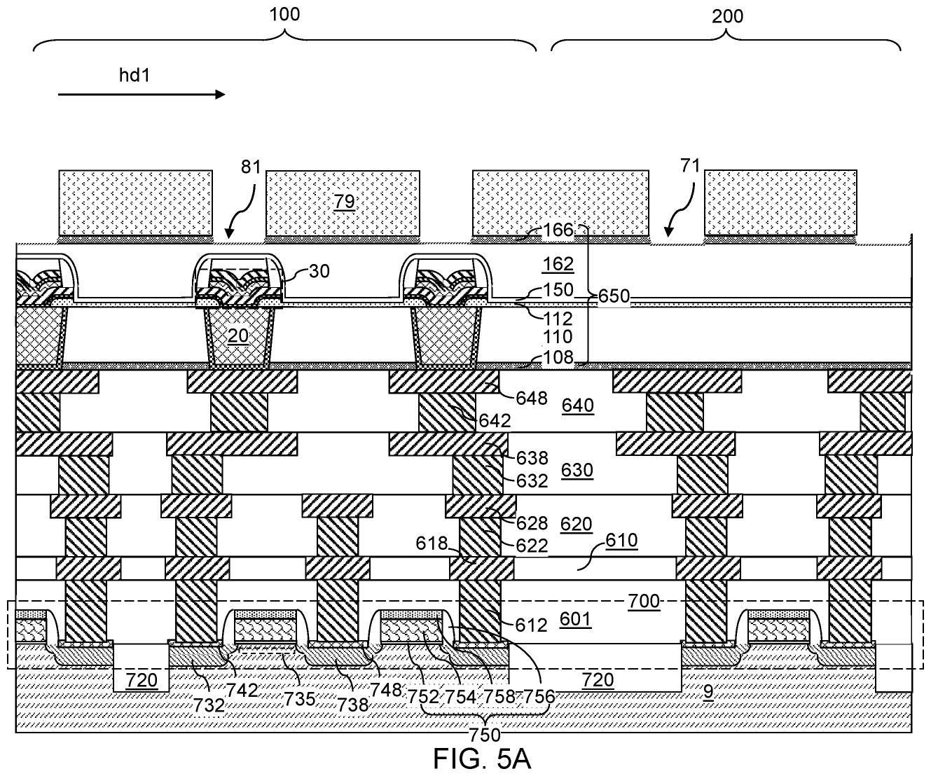

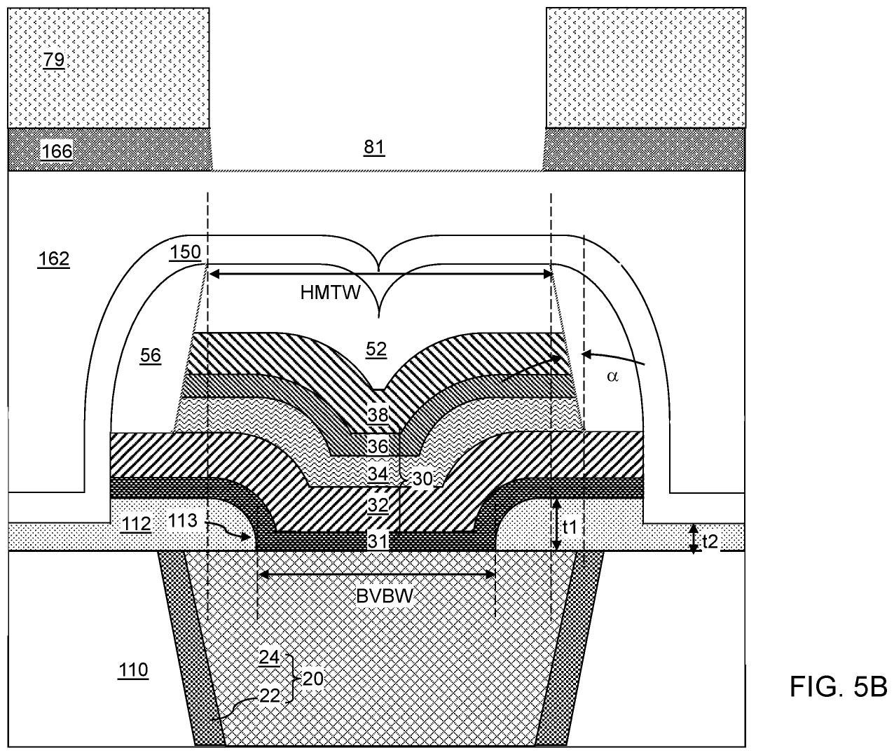

Referring to FIGS. 5A and 5B, a photoresist layer 79 may be applied over the dielectric pad layer 166, and may be lithographically patterned to form a two-dimensional array of openings therein. The opening in the photoresist layer 79 may include first openings that are formed entirely within the area of the periphery of the top surface of an underlying bottom connection via structure 20, and entirely outside the area of the underlying opening 113 in the etch-stop dielectric layer 112. The openings in the photoresist layer 79 may include second openings that are formed in the peripheral region over a respective one of the underlying metal interconnect structures, which may be, for example, a respective underlying fourth metal line structure 648.

An anisotropic etch process may be performed to remove the portions of the dielectric pad layer 166 that are not masked by the photoresist layer 79. First openings 81 may be formed through the dielectric pad layer 166 in the memory array region 100, and second openings 71 may be formed through the dielectric pad layer 166 in the peripheral region 200. In one embodiment, the first openings 81 and the second openings 71 may be discrete openings having a horizontal cross-sectional shape of a circle or an oval. The photoresist layer 79 may be subsequently removed, for example, by ashing.

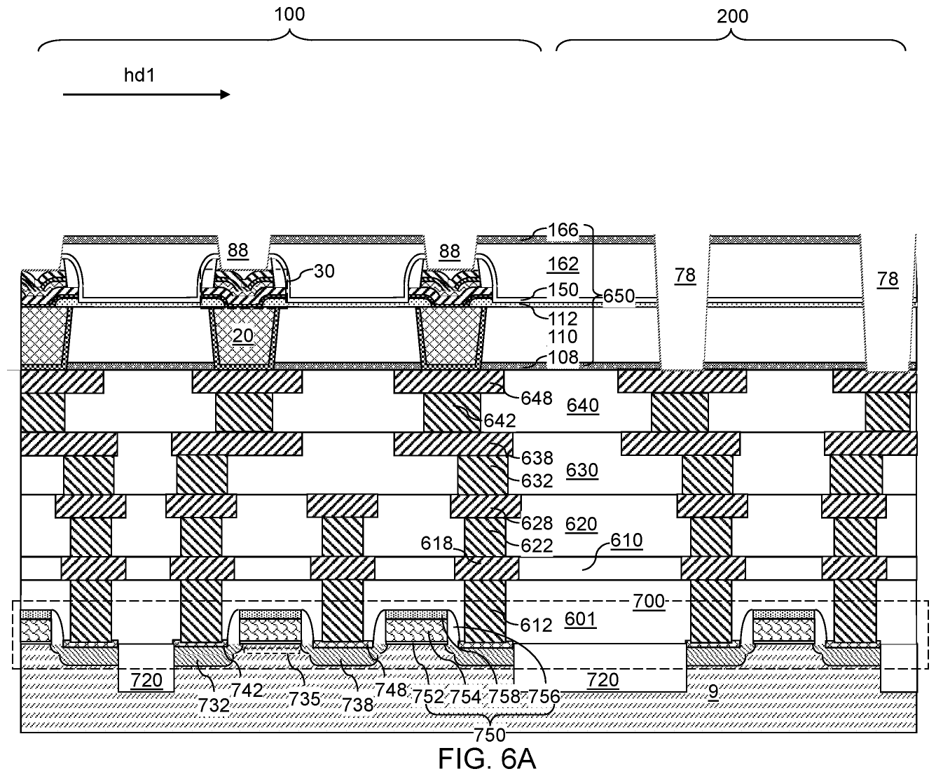

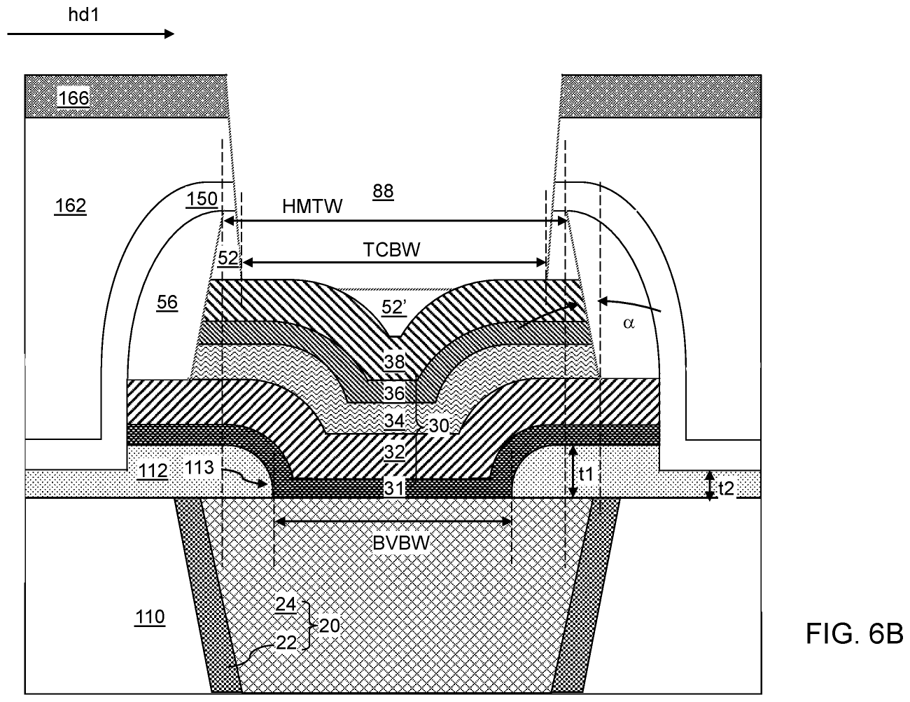

Referring to FIGS. 6A and 6B, a first anisotropic etch process may be performed to transfer the pattern of the openings (81, 71) in the dielectric pad layer 166 through an upper portion of the memory-level dielectric layer 162. First contact via cavities 88 may be formed in the memory array region 100 underneath first openings in the dielectric pad layer 166. Second contact via cavities 78 may be formed in the peripheral region 200 underneath second openings in the dielectric pad layer 166. The first contact via cavities 88 and the second contact via cavities 78 are contact cavities in which metal contact structures may be subsequently formed.

The duration of the first anisotropic etch process may be selected such that a surface segment of each top electrode 38 is exposed to a respective first contact via cavity 88. In one embodiment, the bottom surface of each first contact via cavity 88 may have a third width along the first horizontal direction hd1, which is herein referred to as a top-contact-structure bottom width TCBW. The third width may be less than the second width, i.e., the hard mask top width HMTW. Further, the third width may be greater than the first width, i.e., the bottom-electrode via bottom width BVBW.

Each remaining portion of the hard mask plates 52 located within a divot area of a top surface of a respective top electrode 38 constitutes a hard mask divot-fill material portion 52′. Each hard mask divot-fill material portion 52′ may be located within a divot in the top surface of a top electrode 38, may contact a divot-shaped segment of the top surface of the top electrode 38, and may underlie a respective first contact via cavity 88.

A photoresist layer (not shown) may be applied over the first embodiment structure, and may be lithographically patterned to cover the memory array region 100 without covering the peripheral region 200. An anisotropic etch process may be performed to vertically extend the second contact via cavities 78 through a lower portion of the memory-level dielectric layer 162, the dielectric capping layer 150, the etch-stop dielectric layer 112, the lower connection-via-level dielectric layer 110, and the dielectric cap layer 108. A top surface of a fourth metal line structure 648 may be physically exposed underneath each vertically extended second contact via cavity 78. The photoresist layer may be subsequently removed, for example, by ashing.

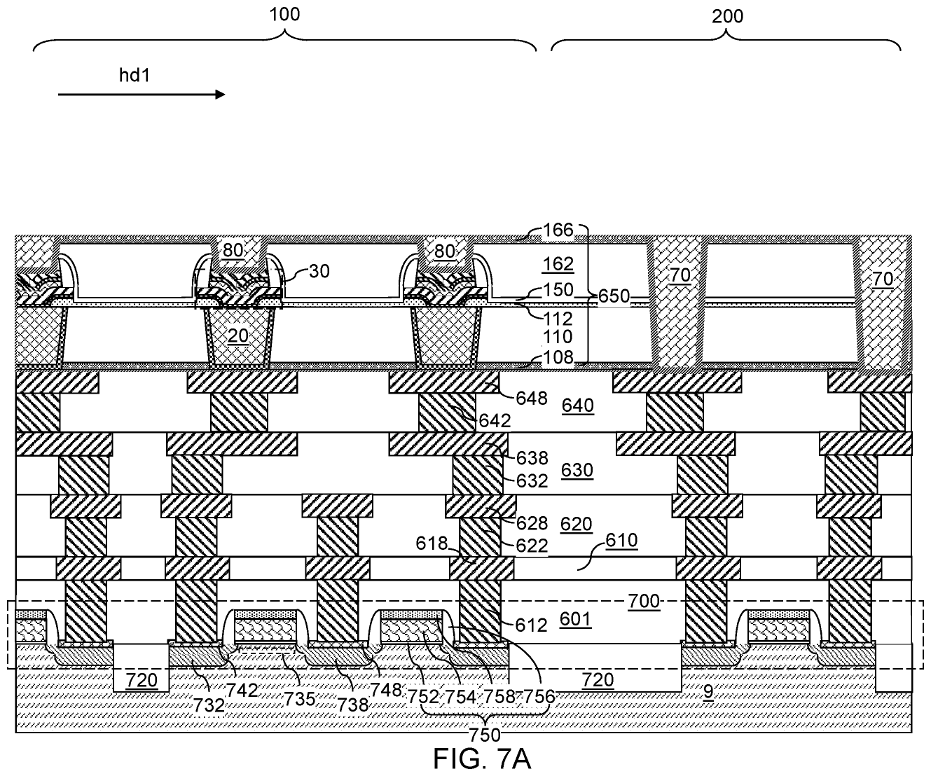

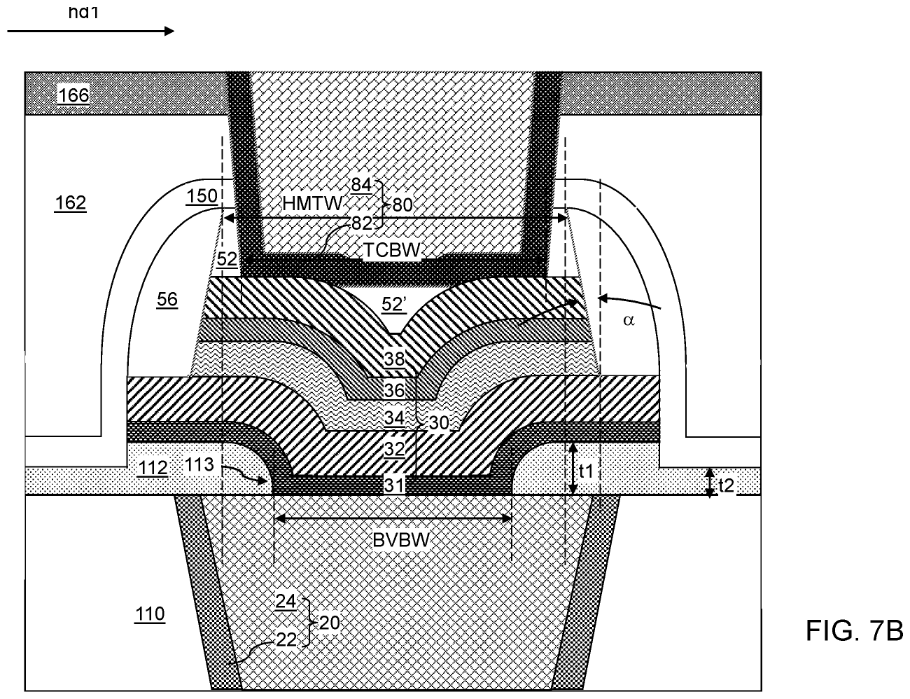

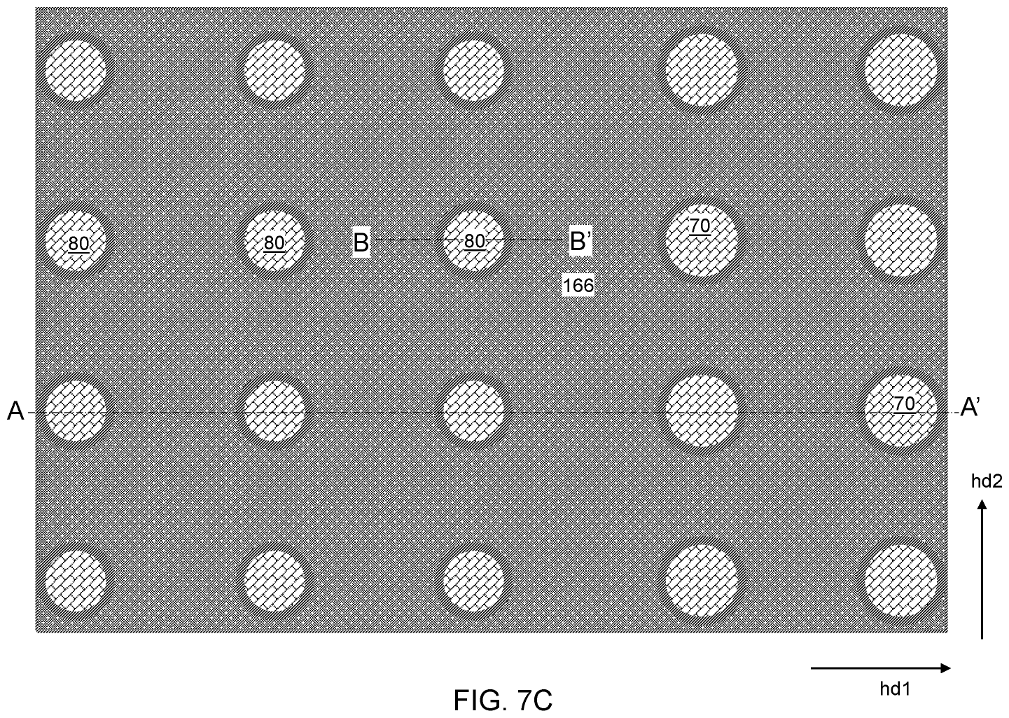

Referring to FIGS. 7A-7C, at least one conductive material may be deposited in the first via cavities 88 and in the second via cavities 78. The at least one conductive material may include a metallic barrier liner material and a metallic fill material. The metallic barrier liner material may include a conductive metallic nitride material such as TiN, TaN, WN, and/or MoN. The metallic barrier liner material may be deposited by physical vapor deposition and/or chemical vapor deposition. The thickness of the metallic barrier liner material may be in a range from 4 nm to 50 nm, such as from 8 nm to 25 nm, although lesser and greater thicknesses may also be used. The metallic fill material comprises a metal such as Cu, W, Mo, Ru, Co, Al, alloys thereof, and/or a layer stack thereof. The metallic fill material may be deposited by physical vapor deposition, chemical vapor deposition, electroplating, electroless plating, or a combination thereof.

Excess portions of the metallic barrier liner material and the metallic fill material may be removed from above the horizontal plane including the top surface of the dielectric pad layer 166 by performing a planarization process. The planarization process may use, for example, a chemical mechanical planarization process and/or a recess etch process. Each remaining patterned portion of the at least one conductive material that fills a respective first contact via cavity 88 constitutes a top electrode contact structure 80, which may be a metal via structure. Each top electrode contact structure 80 may comprise a metallic barrier line 82 comprising the metallic barrier liner material, and a metallic fill material portion 84 comprising the metallic fill material. Each remaining patterned portion of the at least one conductive material that fills a respective second contact via cavity 78 constitutes a peripheral metal interconnect structure 70, which may be a metal via structure. The dielectric pad layer 166 may be collaterally thinned during the planarization process.

In one embodiment, each top electrode contact structure 80 may be formed in a respective first contact cavity 88 on the surface segment of a respective top electrode 38. The bottom surface of each top electrode contact structure 80 may have the third width (such as the top-contact-structure bottom width TCBW) along the first horizontal direction hd1. The third width (such as a top-contact-structure bottom width TCBW) is less than the second width (such as a hard mask top width HMTW), and is greater than the first width (such as a bottom-electrode via bottom width BVBW). Each top electrode contact structure 80 vertically extends through an upper portion of the memory-level dielectric layer 162, and contacts a top surface of a respective top electrode 38. A hard mask divot-fill material portion 52′ may be located within a divot in the top surface of a top electrode 38, may contact a divot-shaped segment of the top surface of the top electrode 38, and may underlie a bottom surface of a top electrode contact structure 80.

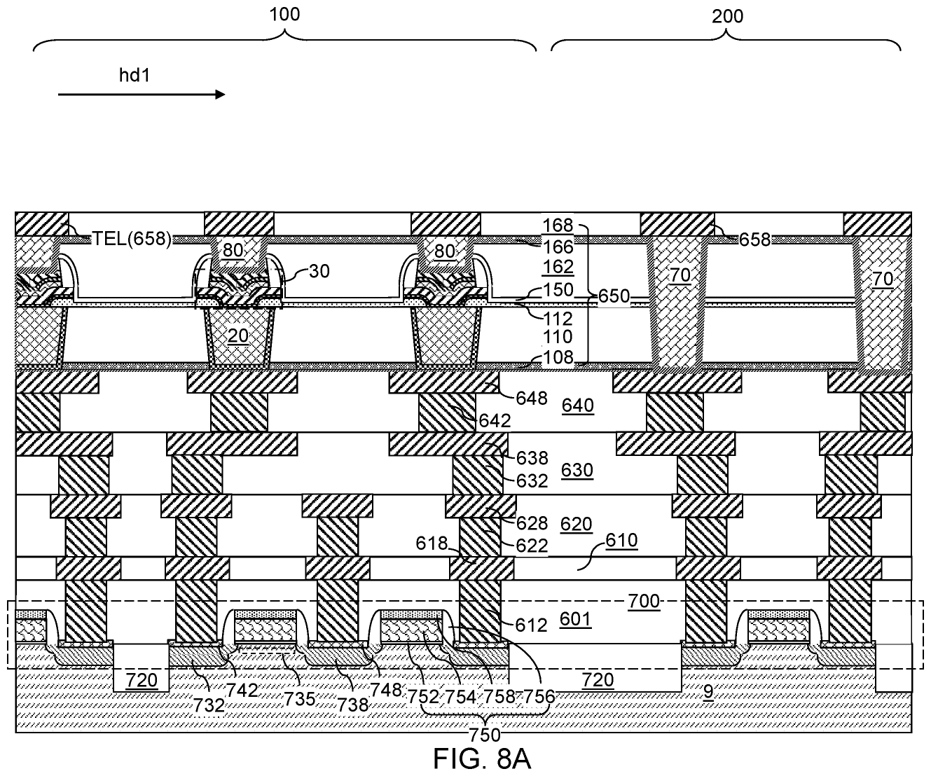

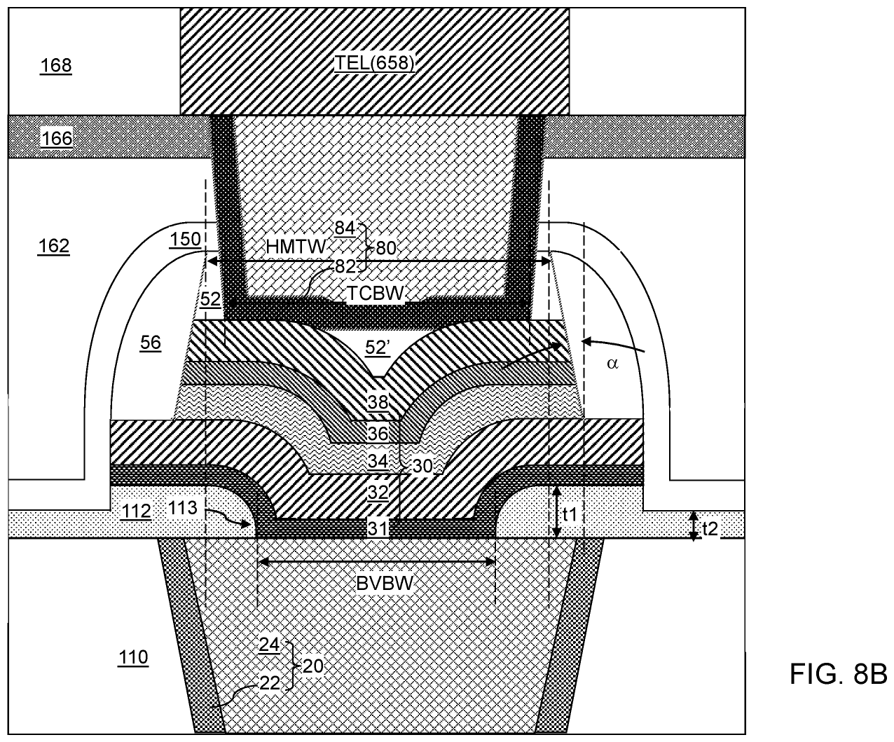

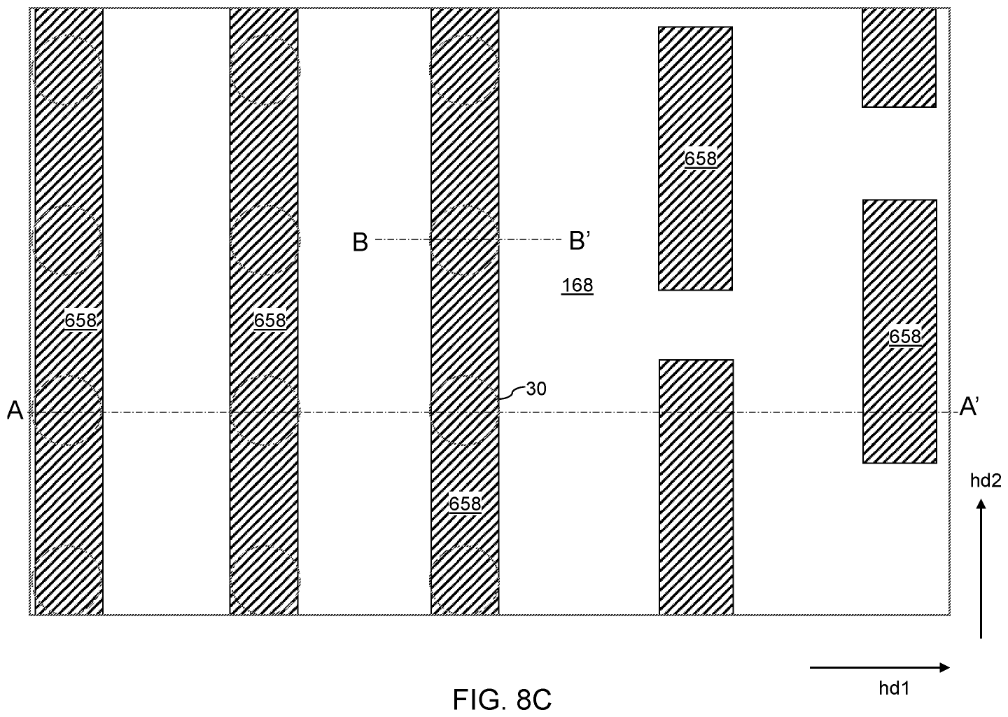

Referring to FIGS. 8A-8C, a line-level dielectric material layer 168 may be deposited over the dielectric pad layer 166, and may be incorporated into the fifth line-and-via-level dielectric material layer 650. Line trenches may be formed through the line-level dielectric material layer 168, for example, by applying and patterning a photoresist layer over the line-level dielectric material layer 168 to form elongated openings in the photoresist layer, and by transferring the pattern of the elongated openings through the line-level dielectric material layer 168 using an anisotropic etch process. The photoresist layer may be removed, and at least one conductive material may be deposited in the line trenches and may be subsequently planarized to form various fifth metal line structures 658.

In one embodiment, a first subset of the fifth metal line structures 658 that are formed in the memory array region 100 comprise top electrode lines TEL for the two-dimensional array of resistive memory cells 30. The top electrode lines TEL may be access lines for accessing a row of resistive memory cells 30 or a column of resistive memory cells 30. As such, the top electrode lines TEL may comprise word lines or bit lines for the two-dimensional array of resistive memory cells 30. In the illustrated example, the top electrode lines TEL may laterally extend along the second horizontal direction hd2, and may be laterally spaced apart from one another along the first horizontal direction hd1. A second subset of the fifth metal line structures 658 may be formed in the peripheral region 200 directly on a top surface of a respective one of the peripheral metal interconnect structures 70.

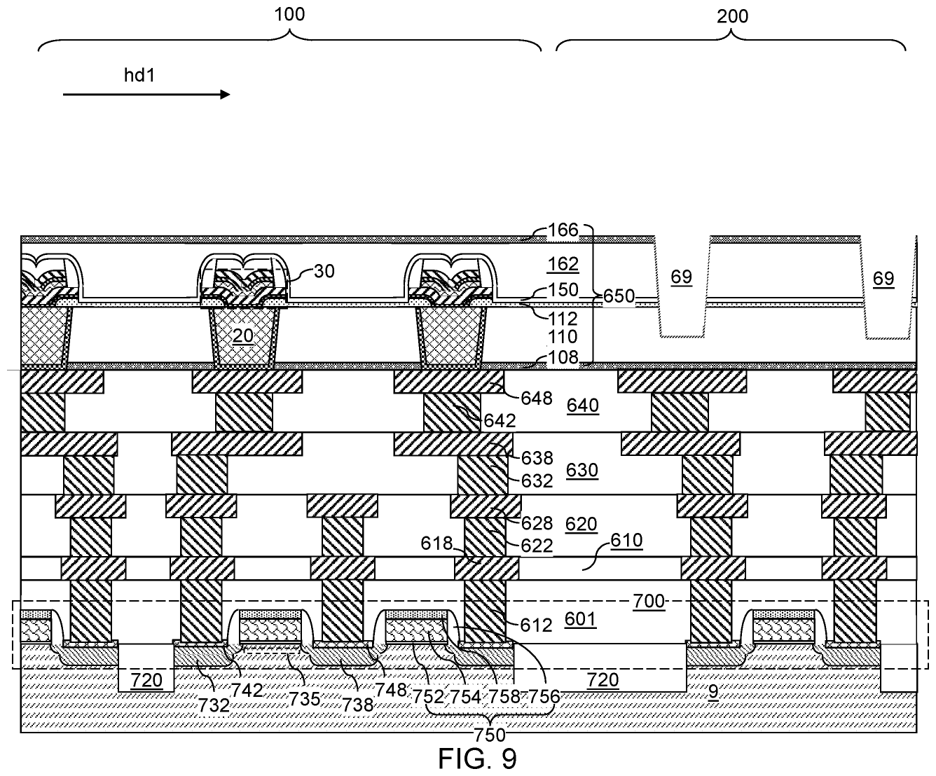

Referring to FIG. 9, an alternative configuration of the first embodiment structure may be derived from the first embodiment structure illustrated in FIGS. 4A and 4B by forming peripheral via cavities 69 in the peripheral region 200. For example, a photoresist layer (not shown) may be applied over the dielectric pad layer 166, and may be lithographically patterned to form openings in the peripheral region 200. An anisotropic etch process may be performed to transfer the pattern of discrete openings in the photoresist layer at least partly through the fifth line-and-via-level dielectric material layer 650 to form the peripheral via cavities 69. The photoresist layer may be subsequently removed, for example, by ashing.

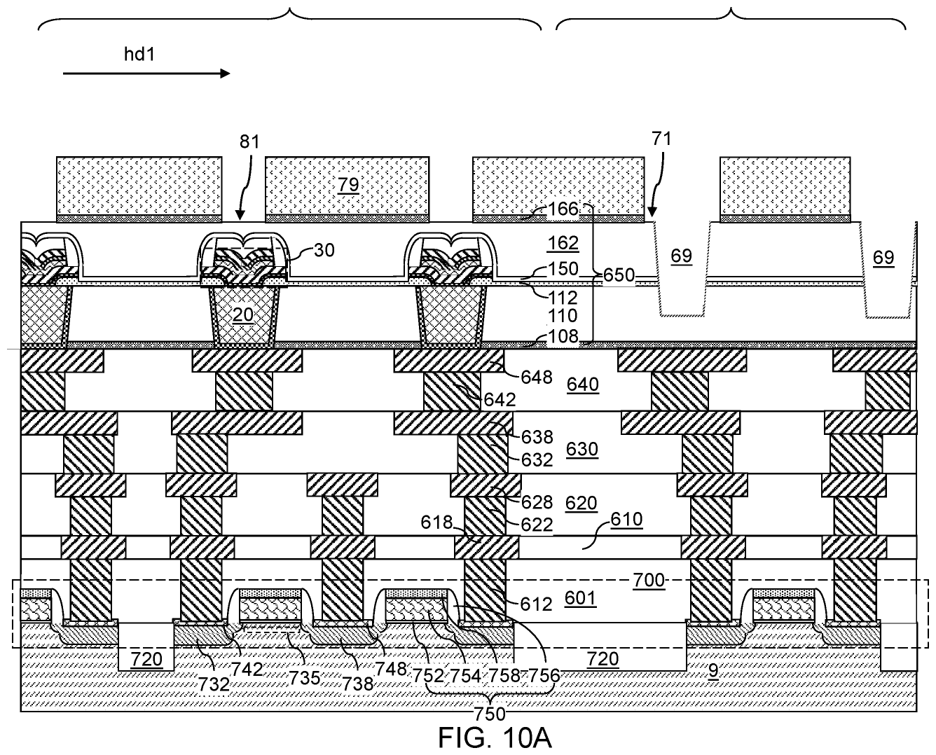

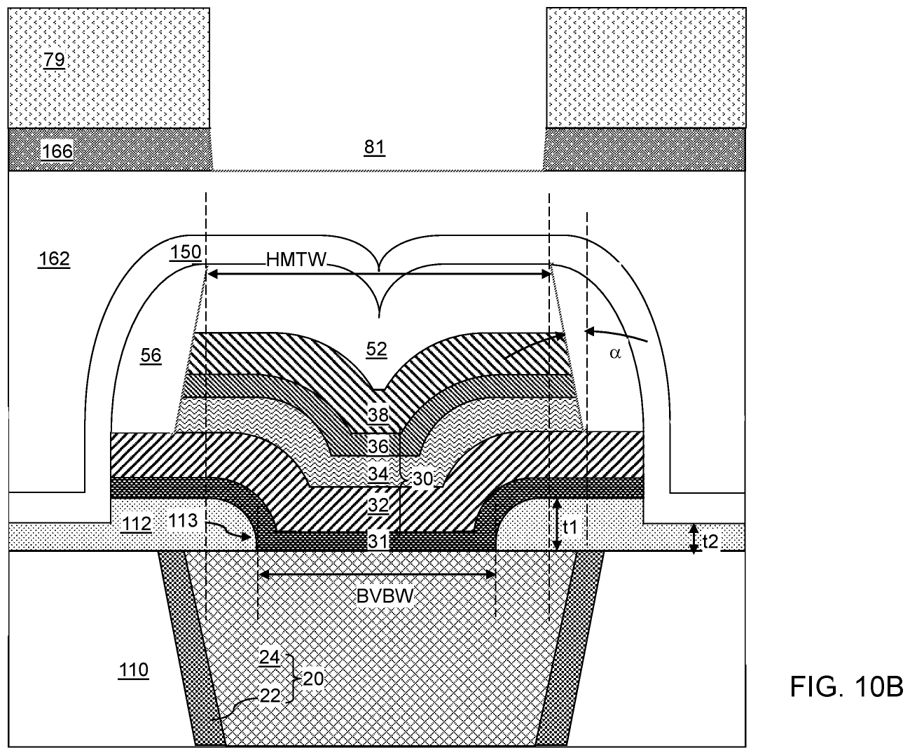

Referring to FIGS. 10A and 10B, a photoresist layer 79 may be applied over the dielectric pad layer 166. In the alternative configuration of the first embodiment structure, the photoresist layer 79 may be patterned to form line-shaped openings therein. For example, the pattern of the line-shaped openings in the photoresist layer may be the same as the pattern of the fifth metal line structures 658 illustrated in FIGS. 8A-8C.

An anisotropic etch process may be performed to remove the portions of the dielectric pad layer 166 that are not masked by the photoresist layer 79. First openings 81 may be formed through the dielectric pad layer 166 in the memory array region 100, and second openings 71 may be formed through the dielectric pad layer 166 in the peripheral region 200. In the alternative configuration of the first embodiment structure, the first openings 81 and the second openings 71 may be line-shaped openings that may be elongated, for example, along the second horizontal direction hd2 which is perpendicular to the first horizontal direction hd1. The photoresist layer 79 may be subsequently removed, for example, by ashing.

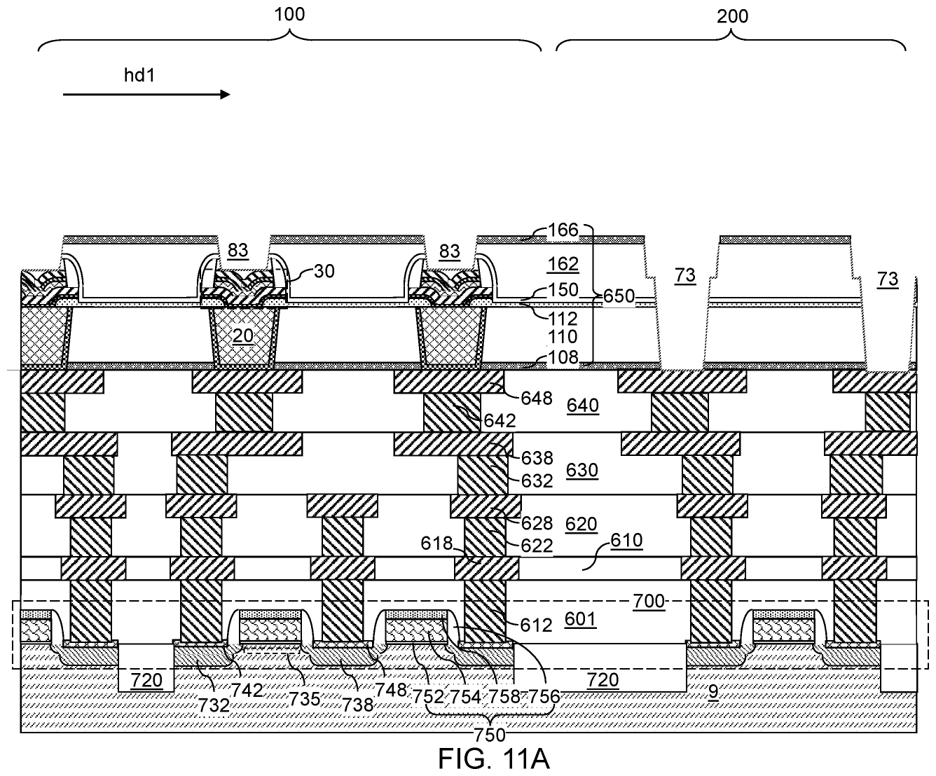

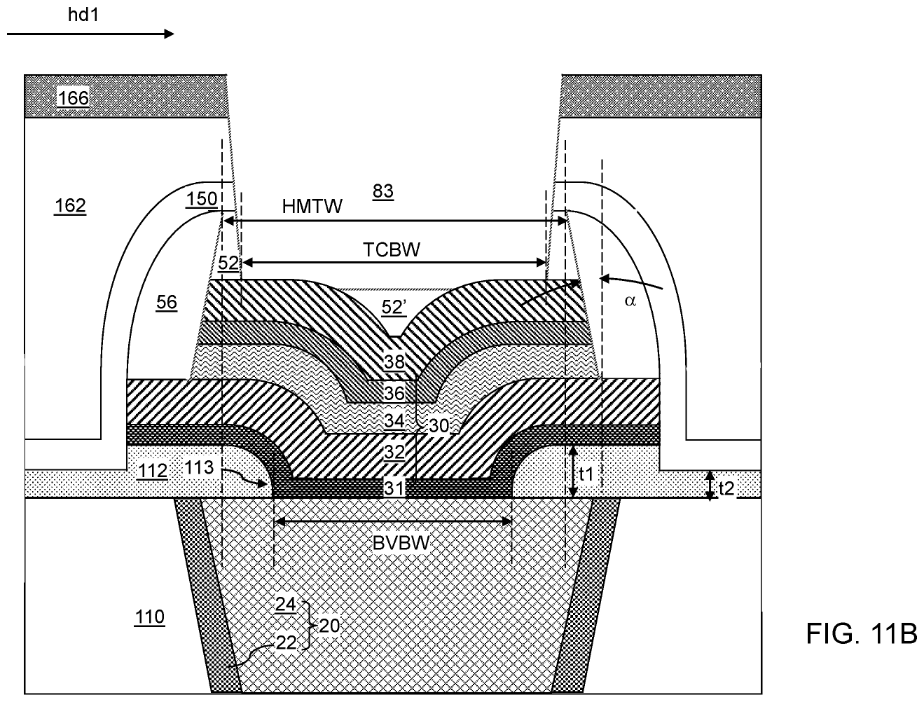

Referring to FIGS. 11A and 11B, a photoresist layer (not shown) may be applied over the dielectric pad layer 166, and may be lithographically patterned to form discrete openings in the peripheral region 200. The discrete openings in the photoresist layer may be formed within the areas of the openings in the dielectric pad layer 166 that are located in the peripheral region 200. An anisotropic etch process may be performed to transfer the pattern of the discrete openings at least through an upper portion of the fifth line-and-via-level dielectric material layer 650 to form via cavities. The photoresist layer may be subsequently removed, for example, by ashing.

An anisotropic etch process may be performed to transfer the pattern of the line-shaped openings in the dielectric pad layer 166 through an upper portion of the memory-level dielectric layer 162. First line cavities 83 may be formed in the memory array region 100 underneath the first openings in the dielectric pad layer 166. Second line cavities may be formed in the peripheral region 200 underneath the second openings in the dielectric pad layer 166. Further, the via cavities in the peripheral region may be vertically extended such that a bottom surface of a fourth metal line structure 648 is exposed underneath each via cavity. Each continuous void that includes at least one via cavity and a second line cavity in the peripheral region 200 constitutes an integrated line-and-via cavity 73. The first line cavities 83 are contact cavities in which metal contact structures are subsequently formed.

The duration of the anisotropic etch process may be selected such that a surface segment of each top electrode 38 is exposed to a respective first line cavity 83. In one embodiment, the bottom surface of each first line cavity 83 may have a third width along the first horizontal direction hd1, which is herein referred to as a top-contact-structure bottom width TCBW. The third width may be less than the second width, i.e., the hard mask top width HMTW. Further, the third width may be greater than the first width, i.e., the bottom-electrode via bottom width BVBW.

Each remaining portion of the hard mask plates 52 located within a divot area of a top surface of a respective top electrode 38 constitutes a hard mask divot-fill material portion 52′. Each hard mask divot-fill material portion 52′ may be located within a divot in the top surface of a top electrode 38, may contact a divot-shaped segment of the top surface of the top electrode 38, and may underlie a respective first line cavity 83. A column of top electrodes 38 arranged along the second horizontal direction hd2 (which is perpendicular to the first horizontal direction hd1) may be physically exposed underneath each first line cavity 83 in the memory array region 100.

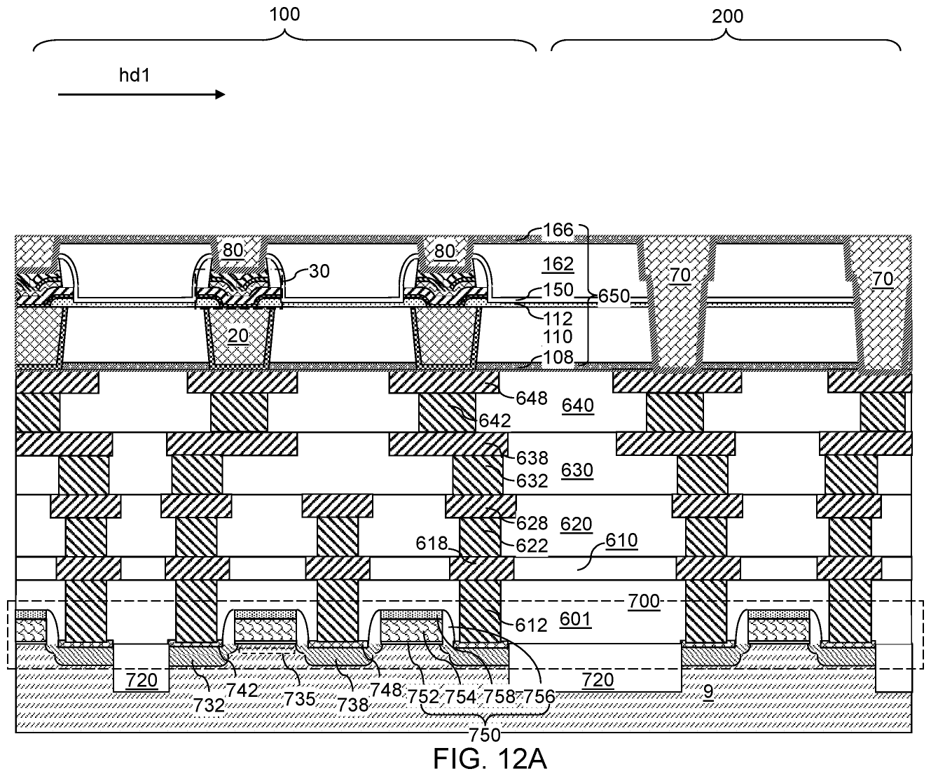

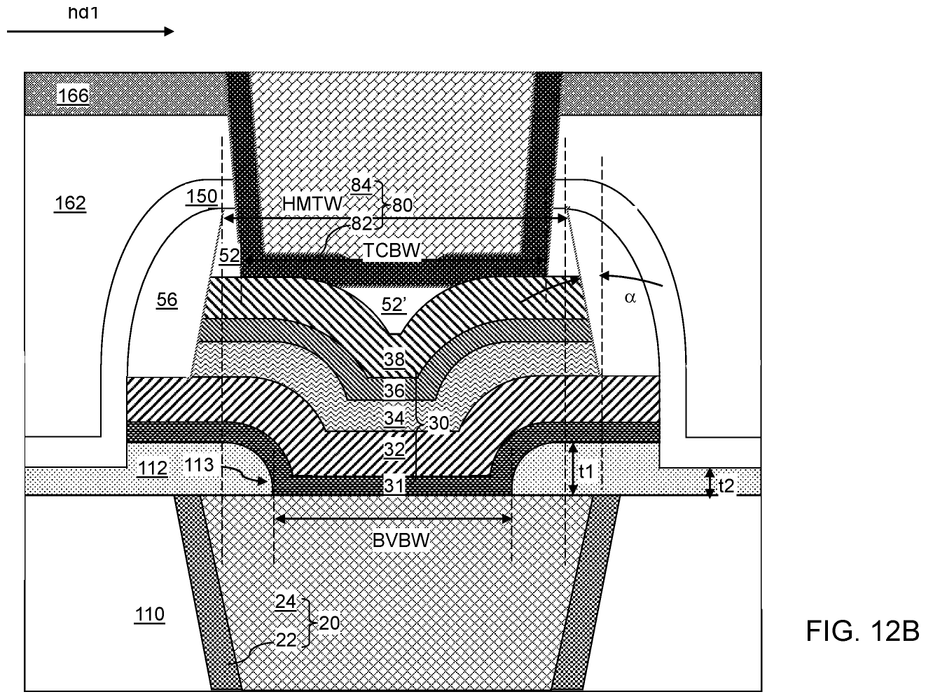

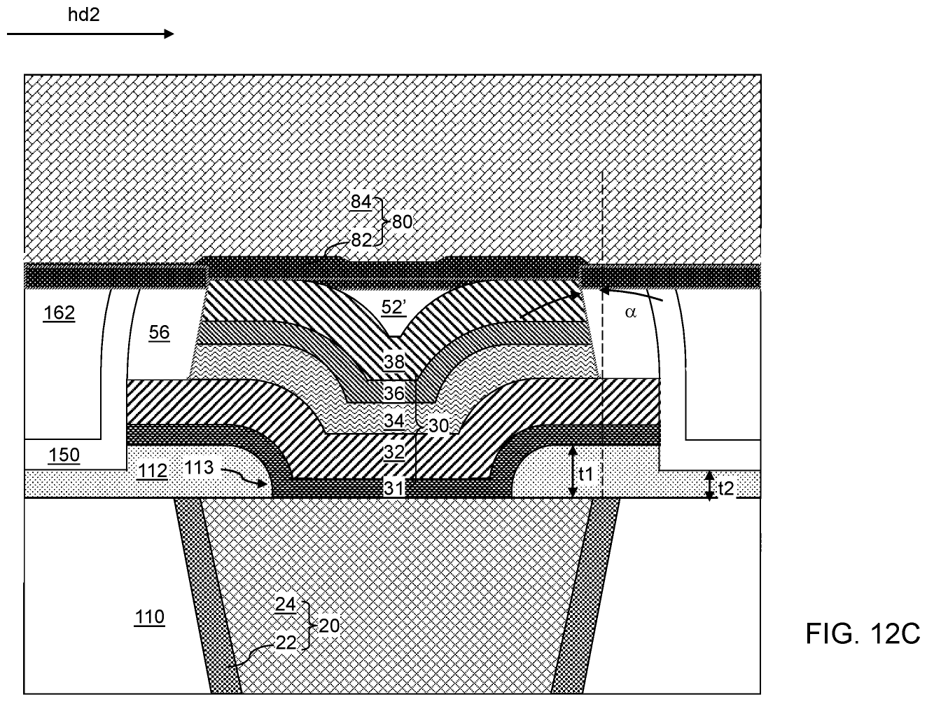

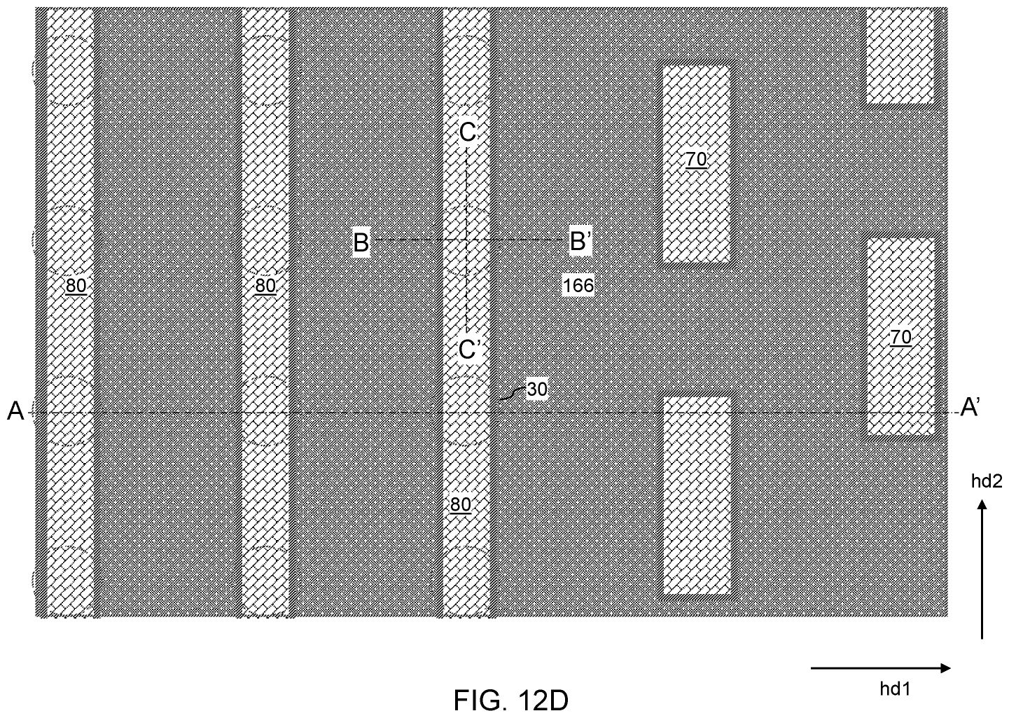

Referring to FIGS. 12A-12D, at least one conductive material may be deposited in the first line cavities 83 and in the integrated line-and-via cavities 73. The at least one conductive material may include a metallic barrier liner material and a metallic fill material. The metallic barrier liner material may include a conductive metallic nitride material such as TiN, TaN, WN, and/or MoN. The metallic barrier liner material may be deposited by physical vapor deposition and/or chemical vapor deposition. The thickness of the metallic barrier liner material may be in a range from 4 nm to 50 nm, such as from 8 nm to 25 nm, although lesser and greater thicknesses may also be used. The metallic fill material comprises a metal such as Cu, W, Mo, Ru, Co, Al, alloys thereof, and/or a layer stack thereof. The metallic fill material may be deposited by physical vapor deposition, chemical vapor deposition, electroplating, electroless plating, or a combination thereof.

Excess portions of the metallic barrier liner material and the metallic fill material may be removed from above the horizontal plane including the top surface of the dielectric pad layer 166 by a performing a planarization process. The planarization process may use, for example, a chemical mechanical planarization process and/or a recess etch process. Each remaining patterned portion of the at least one conductive material that fills a respective first line cavity 83 constitutes a top electrode contact structure 80, which may be a metal line structure. Each top electrode contact structure 80 may comprise a metallic barrier line 82 comprising the metallic barrier liner material, and a metallic fill material portion 84 comprising the metallic fill material. Each remaining patterned portion of the at least one conductive material that fills a respective integrated line and via cavity 73 constitutes a peripheral metal interconnect structure 70, which may be an integrated line-and-via structure. The dielectric pad layer 166 may be collaterally thinned during the planarization process.

In one embodiment, each top electrode contact structure 80 may be formed in a respective first line cavity 83 on the surface segment of a respective top electrode 38. The bottom surface of each top electrode contact structure 80 may have the third width (such as the top-contact-structure bottom width TCBW) along the first horizontal direction hd1. The third width (such as a top-contact-structure bottom width TCBW) is less than the second width (such as a hard mask top width HMTW), and is greater than the first width (such as a bottom-electrode via bottom width BVBW). Each top electrode contact structure 80 vertically extends through an upper portion of the memory-level dielectric layer 162, and contacts a top surface of a respective top electrode 38. A hard mask divot-fill material portion 52′ may be located within a divot in the top surface of a top electrode 38, may contact a divot-shaped segment of the top surface of the top electrode 38, and may underlie a bottom surface of a top electrode contact structure 80.

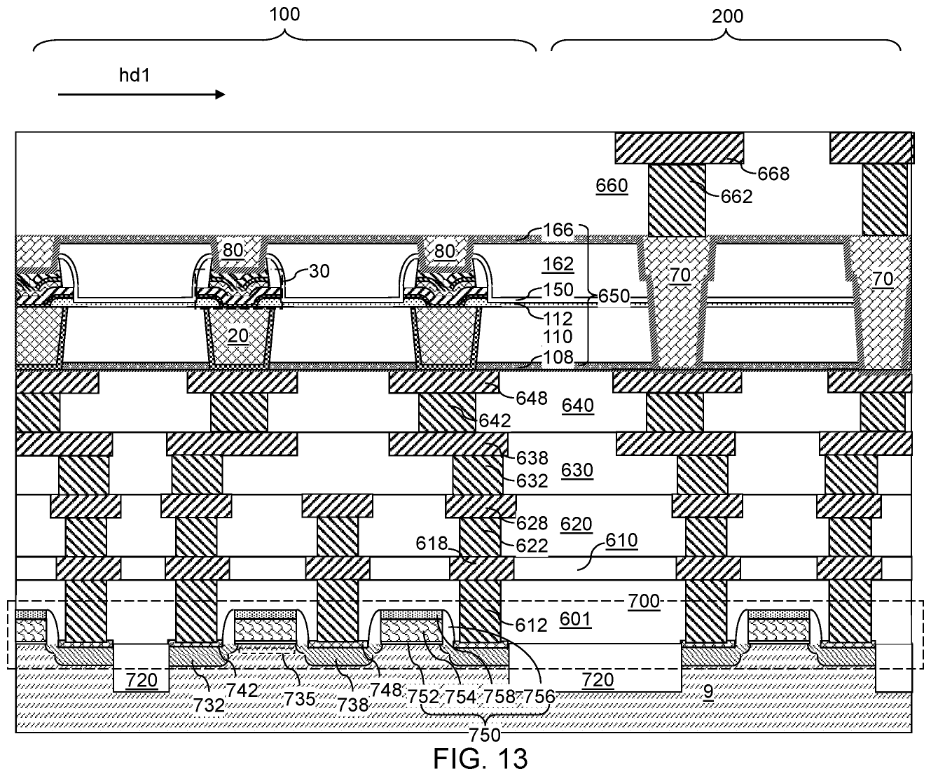

Referring to FIG. 13, a sixth line-and-via-level dielectric material layer 660 may be formed above the fifth line-and-via-level dielectric material layer 650. Fifth metal via structures 662 and sixth metal line structures 668 may be formed in the sixth line-and-via-level dielectric material layer 660 to provide electrical connection to the top electrode contact structure 80 (which are formed as metal line structures) and the peripheral metal interconnect structure 70 (which may be formed as integrated line-and-via structures including a respective metal line structure and a respective set of at least one metal via structure).

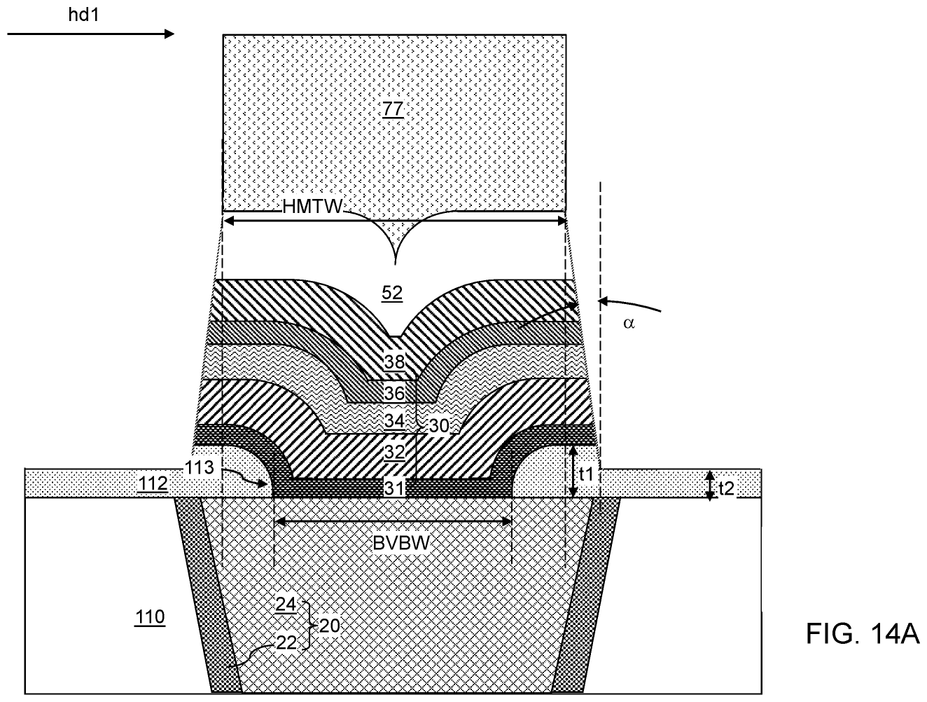

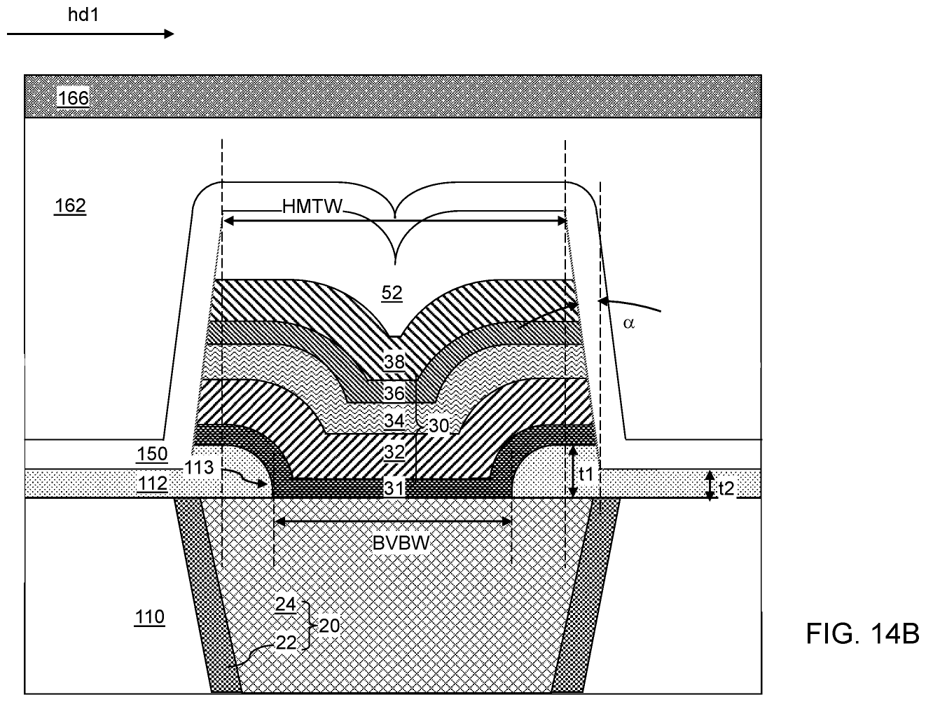

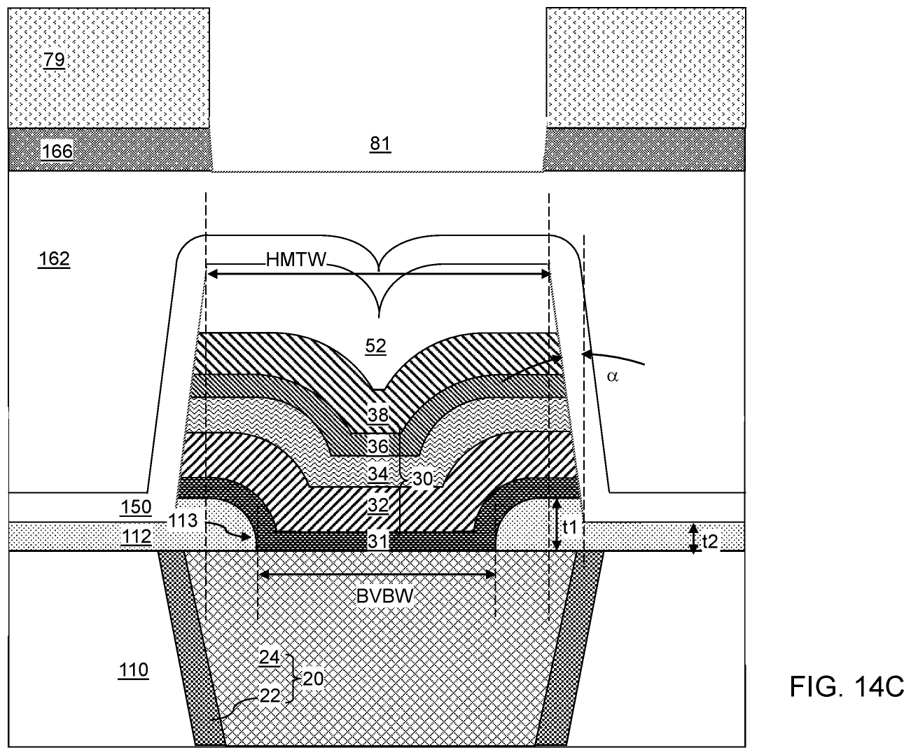

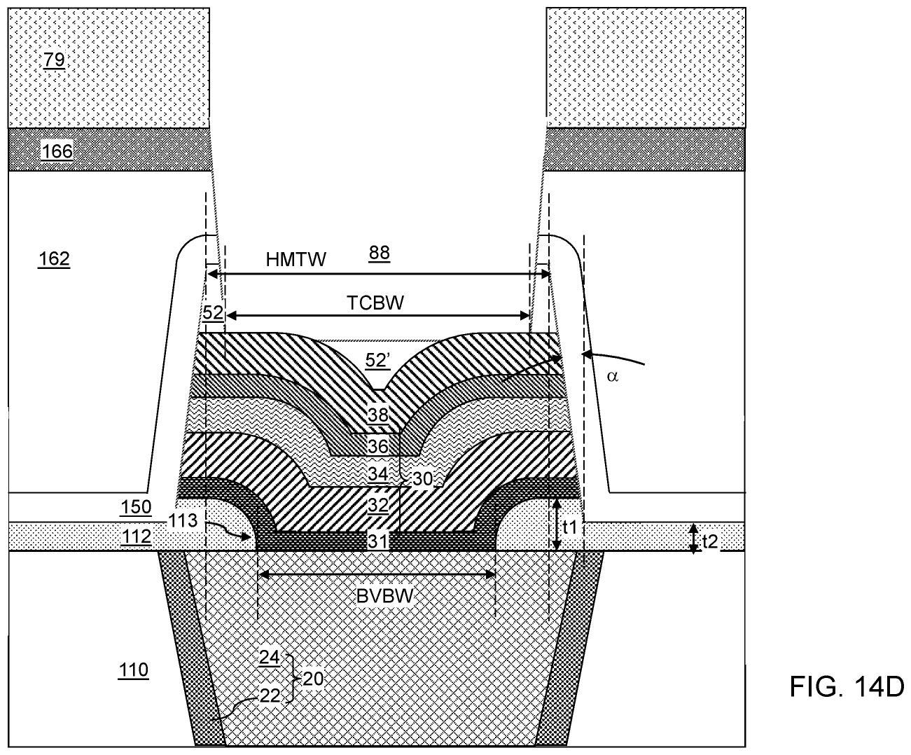

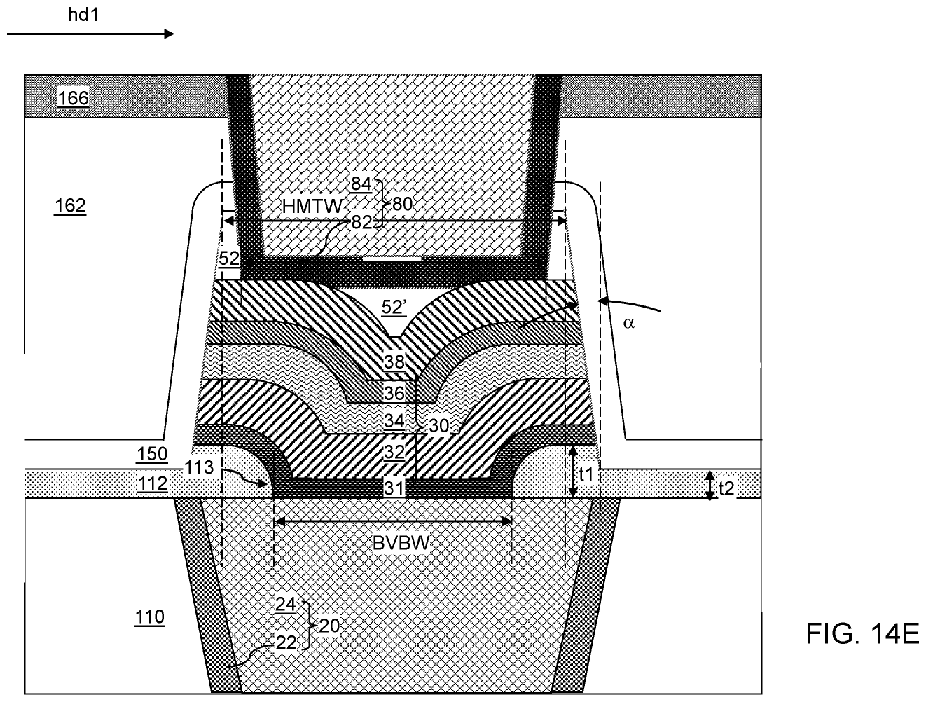

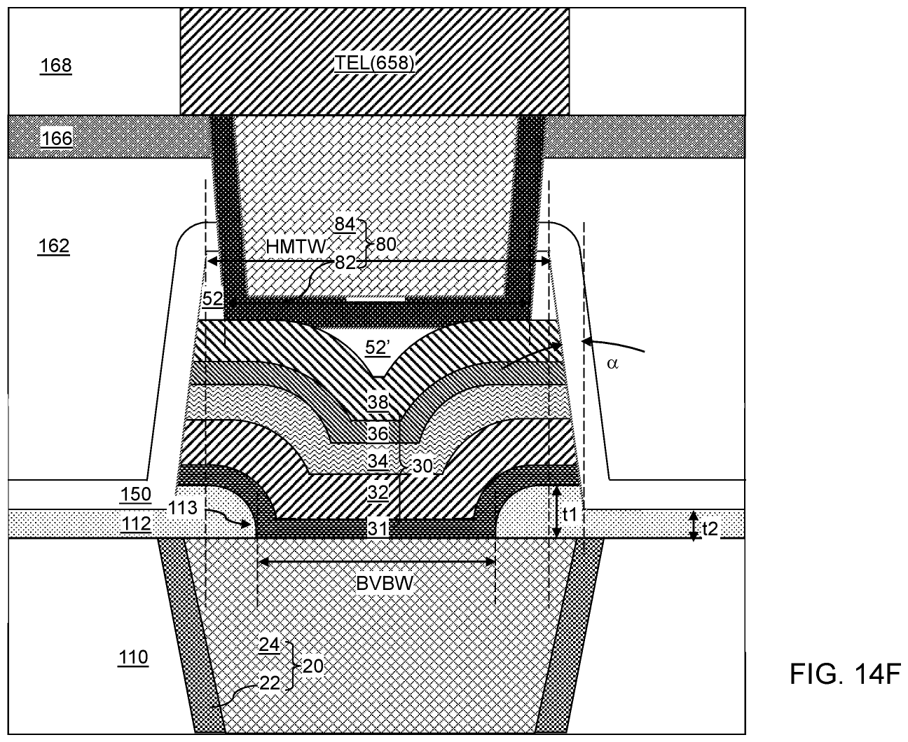

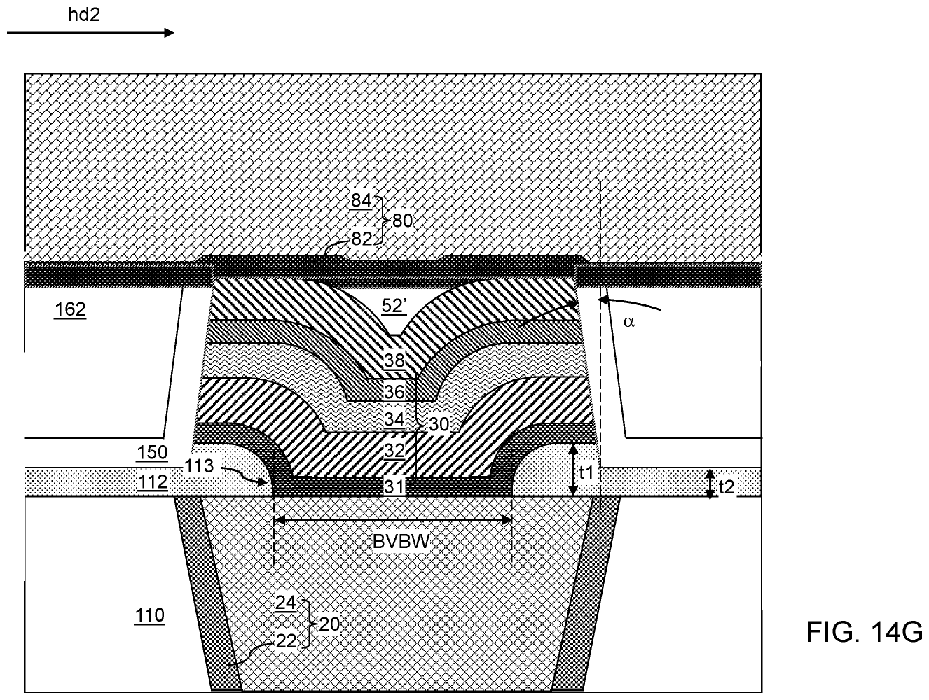

FIGS. 14A-14F are sequential vertical cross-sectional views of a region of a second embodiment structure during formation of a resistive memory cell 30 according to an embodiment of the present disclosure. FIG. 14G is a vertical cross-sectional view of an alternative configuration of the second embodiment structure according to an embodiment of the present disclosure.

Referring to FIG. 14A, a second embodiment structure of the present disclosure may be derived from the first embodiment structure illustrated in FIG. 3B by performing a second anisotropic etch process after performing the first anisotropic etch process. In this embodiment, the patterned photoresist material portions 77 may be used as the etch mask for the second anisotropic etch process. Unmasked portions of the bottom electrode material layer (31L, 32L) may be etched. The second anisotropic etch process may collaterally etch unmasked portions of the etch-stop dielectric layer 112. Etched portions of the etch-stop dielectric layer 112 may have a second thickness t2 which is less than the first thickness t1. The patterned photoresist material portions 77 may be subsequently removed, for example, by ashing.

Each patterned portion of the bottom electrode material layer (31L, 32L) constitutes a bottom electrode (31, 32). Each bottom electrode (31, 32) may comprise a combination of a bottom metallic barrier layer 31 and a bottom metal plate 32. The bottom metallic barrier layer 31 may be a patterned portion of the bottom metallic barrier material layer 31L, and the bottom metal plate 32 may be a patterned portion of the bottom metal layer 32L.

In one embodiment, each bottom electrode (31, 32) may comprise a top surface that includes an annular top surface segment and a central recessed horizontal surface segment that underlies a downward-protruding portion of an overlying memory material layer 34. According to an aspect of the present disclosure, the lateral extent of the central recessed horizontal surface segment along the first horizontal direction hd1 is less than a first width (such as a bottom-electrode via bottom width BVBW) of an underlying opening 113 in the etch-stop dielectric layer 112.

The thickness of a horizontally-extending portion of each hard mask plate 52 may be in a range from 25 nm to 180 nm, and/or from 40 nm to 100 nm, although lesser and greater thicknesses may also be used. The periphery of the top surface of each hard mask plate 52 may have a second width along the first horizontal direction hd1, which is herein referred to as a hard mask top width HMTW. The second width is greater than the first width (such as a bottom-electrode via bottom width BVBW).

Generally, the top electrode material layer 38L, the continuous memory material layer 34L, and the bottom electrode material layer (31L, 32L) may be patterned into a two-dimensional array of resistive memory cells 30. Each resistive memory cell 30 comprises a top electrode 38, an optional capping material plate 36, a memory material layer 34, and a bottom electrode (31, 32). In one embodiment, each bottom electrode (31, 32) comprises a plate portion overlying the etch-stop dielectric layer 112 and a via portion located within the opening 113 in the etch-stop dielectric layer 112. In other words, the via portion vertically extends downward into a respective opening 113 in the etch-stop dielectric layer 112. In one embodiment, the memory material layer 34 overlies the bottom electrode (31, 32) and is configured to provide at least two states having different electrical resistance. In one embodiment, within each resistive memory cell 30, the memory material layer 34 is located entirely within an area of a top surface of an underlying bottom connection via structure 20 (which is a metallic via structure) in a plan view upon patterning of the memory material layer 34. The top electrode 38 overlies the memory material layer 34.

As discussed above, the first anisotropic etch process may use an etch chemistry that minimizes erosion of the hard mask plates 52. In this embodiment, the first anisotropic etch process may use a hydrogen-free etchant such as CF₄ or SF₆ to sustain a substantially vertical sidewall profile for the hard mask plates 52. A tapered surface may extend straight from the periphery of the top surface of a hard mask plate 52 at least to a periphery of a bottom surface of a bottom electrode (31,32) at a taper angle α with respect to a vertical direction. The taper angle α may be in a range from 5 degrees to 20 degrees, such as from 5 degrees to 15 degrees. The array of patterned photoresist material portions 77 may be subsequently removed, for example, by ashing. In one embodiment, a tapered surface may extend straight from the periphery of the top surface of a hard mask plate 52 to a periphery of a portion of the etch-stop dielectric layer 112 having the second thickness t2 at the taper angle α with respect to a vertical direction.

In one embodiment, the etch-stop dielectric layer 112 comprises an annular portion that laterally surrounds an opening 113 in the etch-stop dielectric layer 112 and having a first thickness t1, and a planar layer portion having a second thickness t2 that is less than the first thickness t1 and laterally spaced from the opening 113 by the annular portion. Thus, the annular portion has the first thickness t1 and includes an opening 113 therethrough, and the planar layer portion has a second thickness t2 that is less than the first thickness t1 and is laterally spaced from the opening 113 by the annular portion.

Referring to FIG. 14B, the processing steps described with reference to FIGS. 4A and 4B may be performed to form a dielectric capping layer 150, a memory-level dielectric layer 162, and a dielectric pad layer 166. In this embodiment, the dielectric capping layer 150 may be formed directly on straight sidewalls of the resistive memory cells 30.

Referring to FIG. 14C, the processing steps described with reference to FIGS. 5A and 5B may be performed to form first openings 81 and second openings 71 (See FIG. 5A) through the dielectric pad layer 166.

Referring to FIG. 14D, the processing steps described with reference to FIGS. 6A and 6B may be performed to form first contact via cavities 88 and second contact via cavities 78 (See FIG. 6A).

Referring to FIG. 14E, the processing steps described with reference to FIGS. 7A-7C may be performed to form top electrode contact structures 80 and peripheral metal interconnect structures 70 (See FIGS. 7A and 7C).

Referring to FIG. 14F, the processing steps described with reference to FIGS. 8A-8C may be performed to form a line-level dielectric material layer 168, which may be incorporated into the fifth line-and-via-level dielectric material layer 650. Various fifth metal line structures 658 may be formed in the line-level dielectric material layer 168 to provide electrical connection to the top electrode contact structures 80 and the peripheral metal interconnect structures 70.

Referring to FIG. 14G, an alternative configuration of the second embodiment structure may be derived from the second embodiment structure illustrated in FIG. 14B by performing the processing steps described with reference to FIGS. 9, 10A and 10B, 11A and 11B, and 12A-12D.

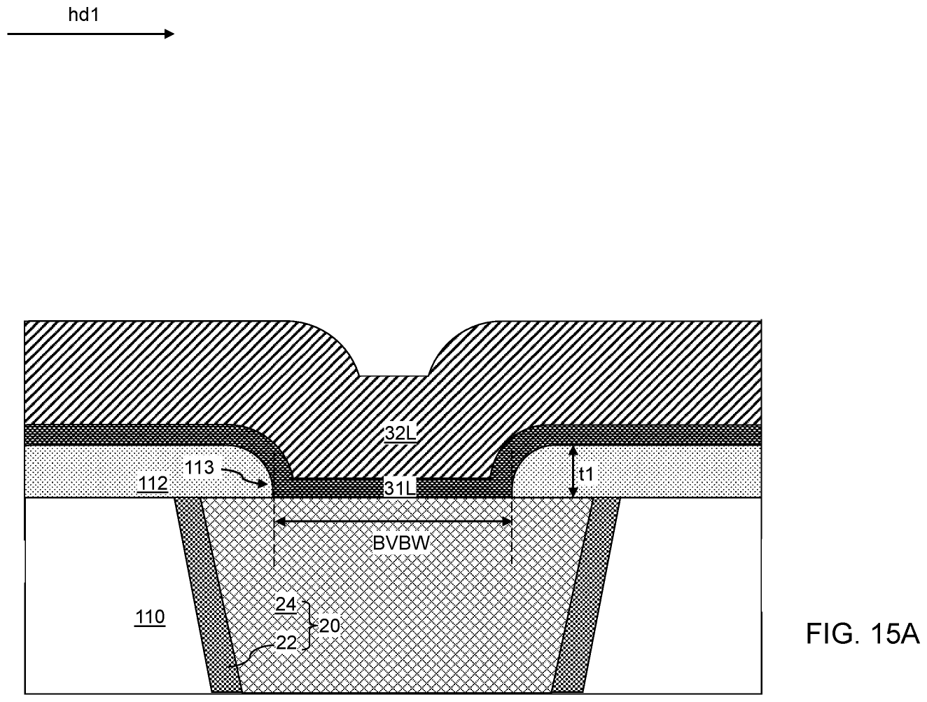

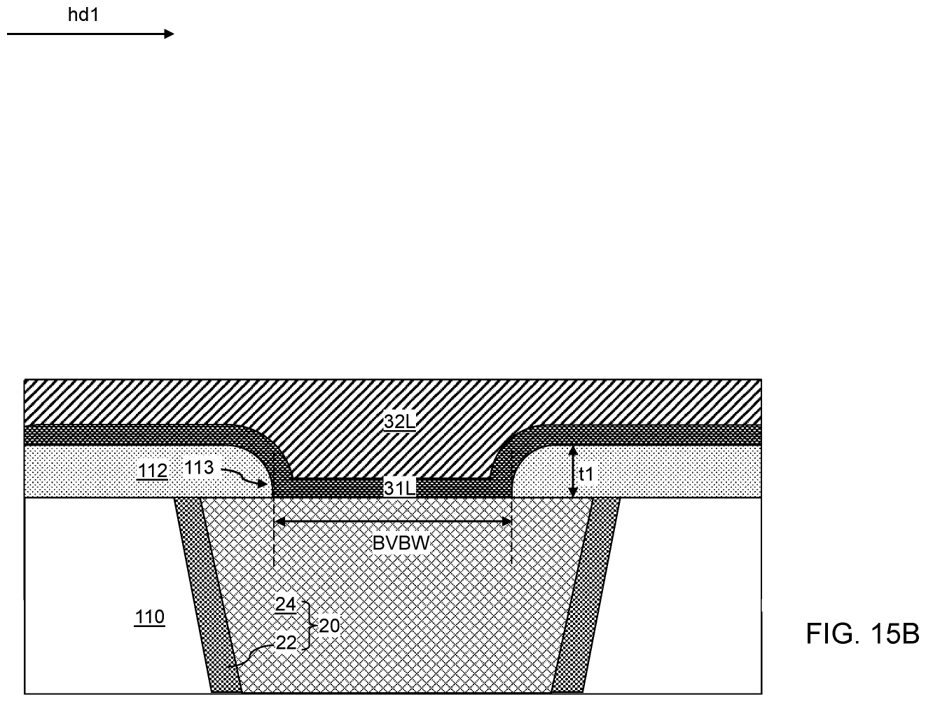

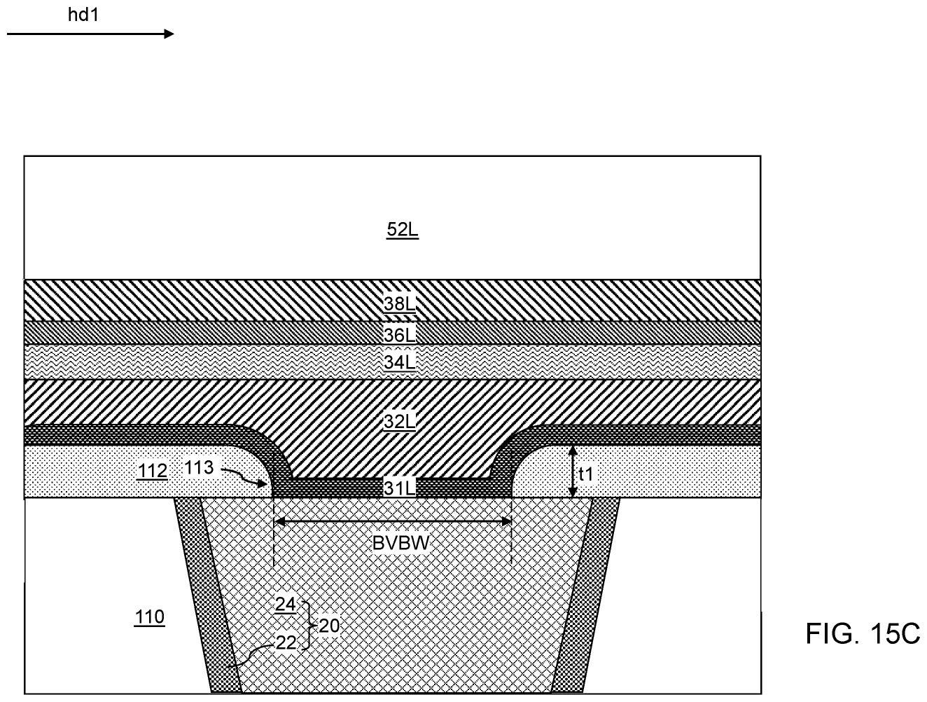

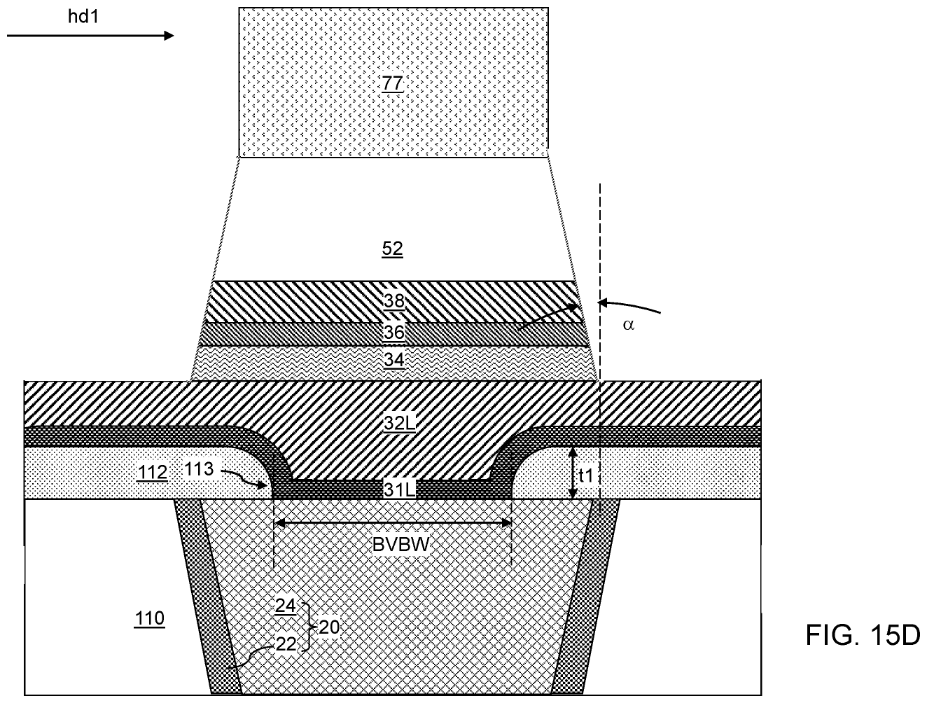

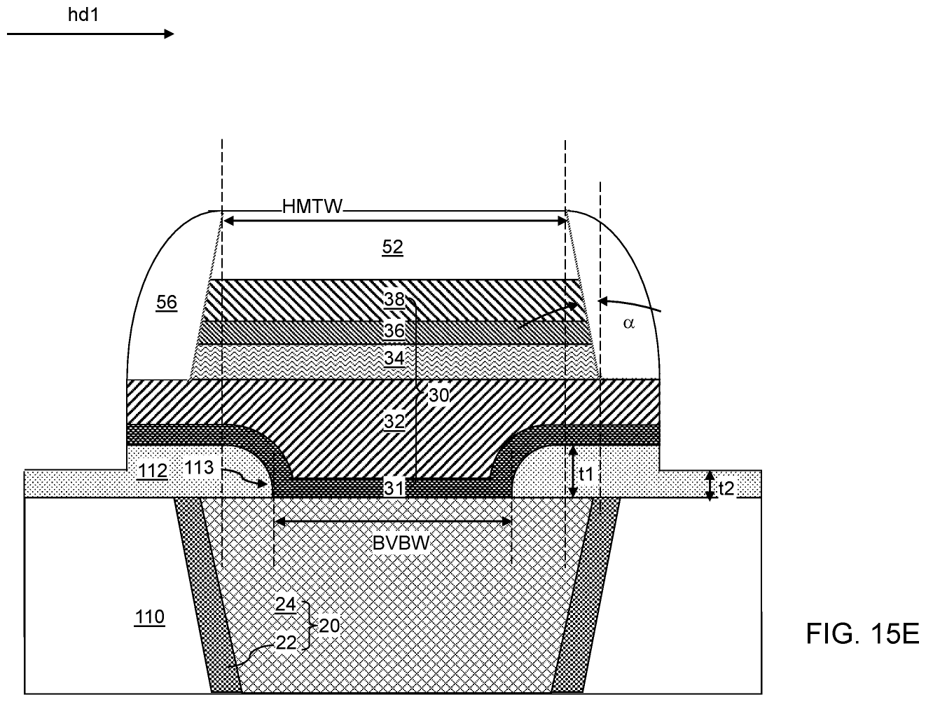

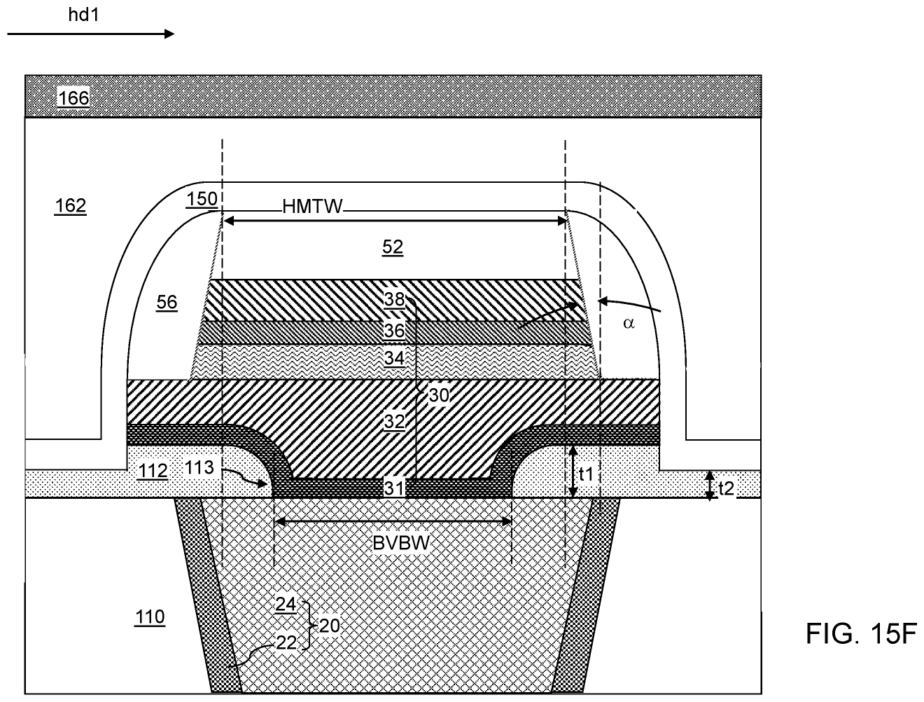

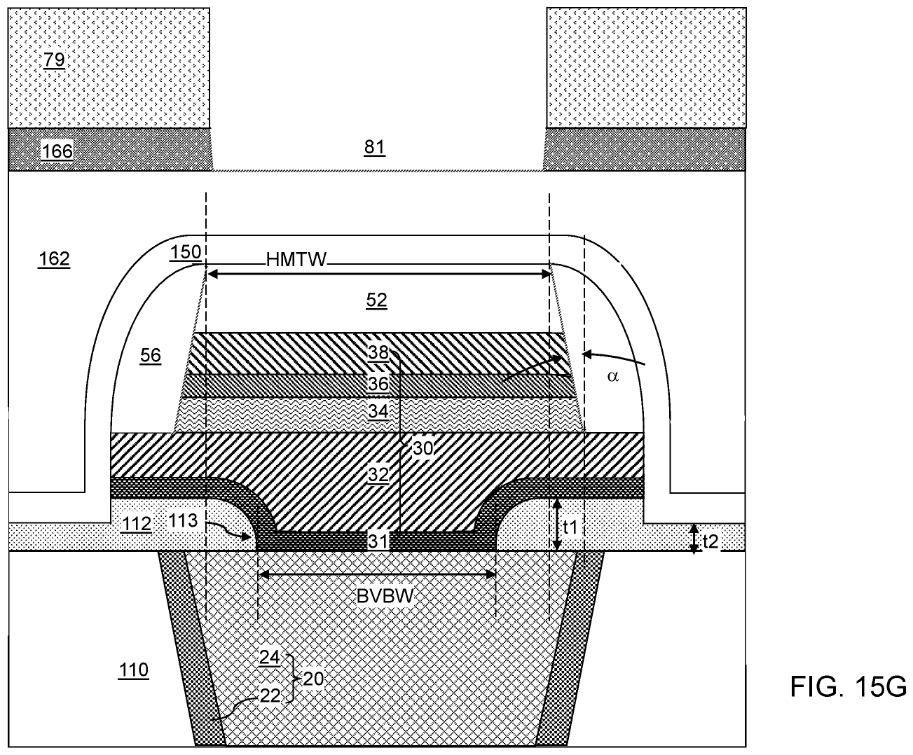

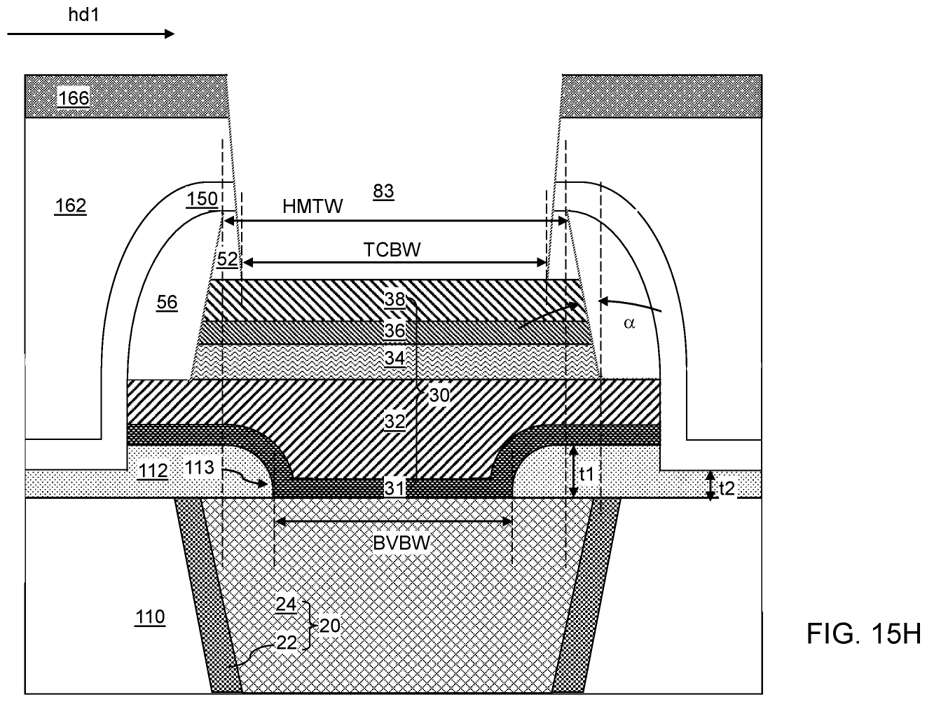

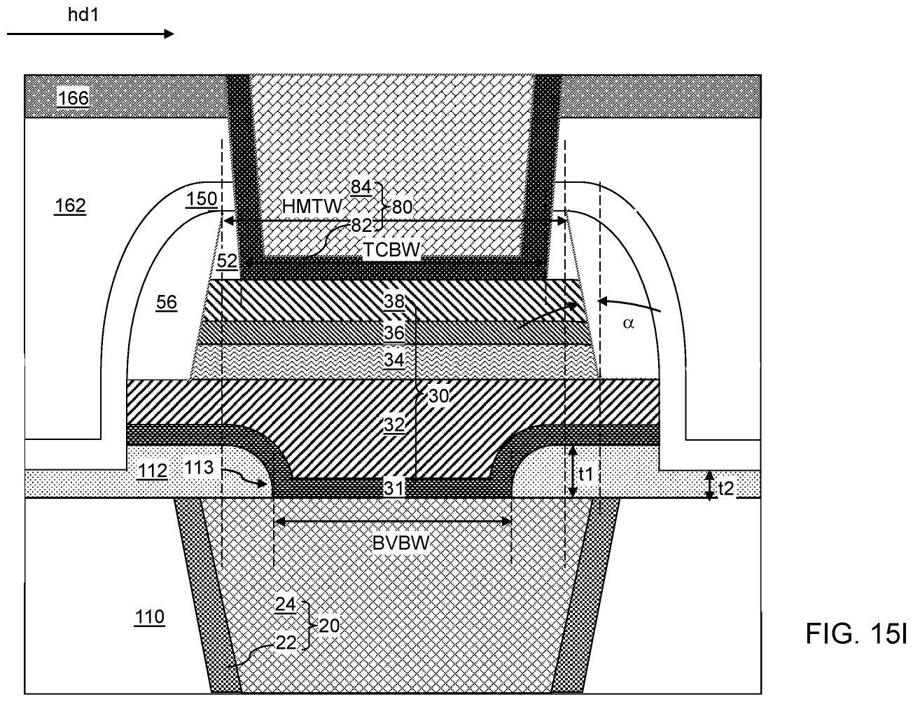

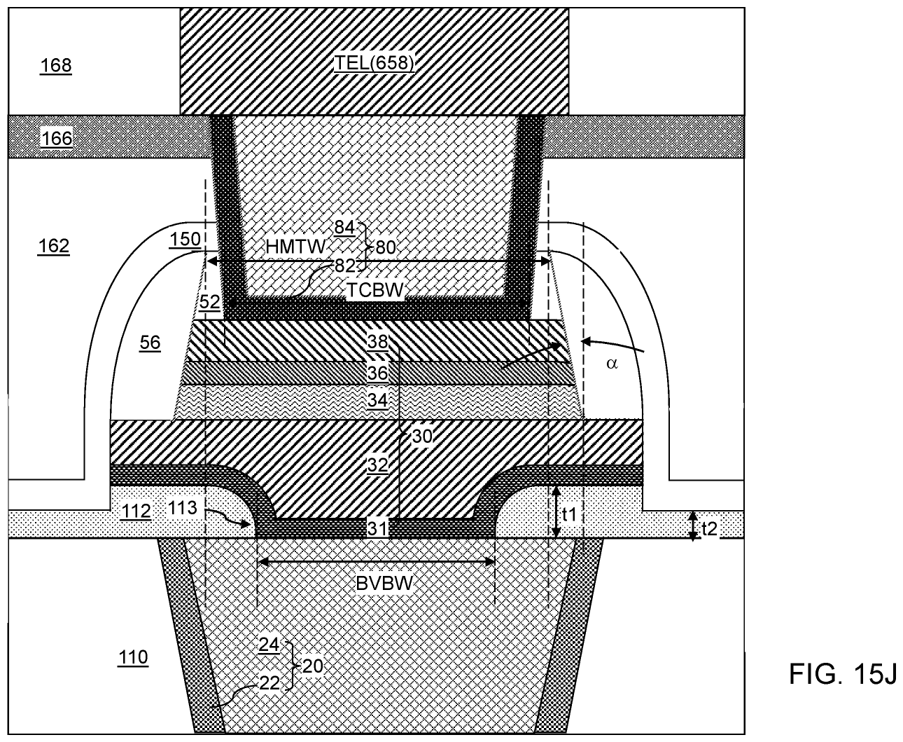

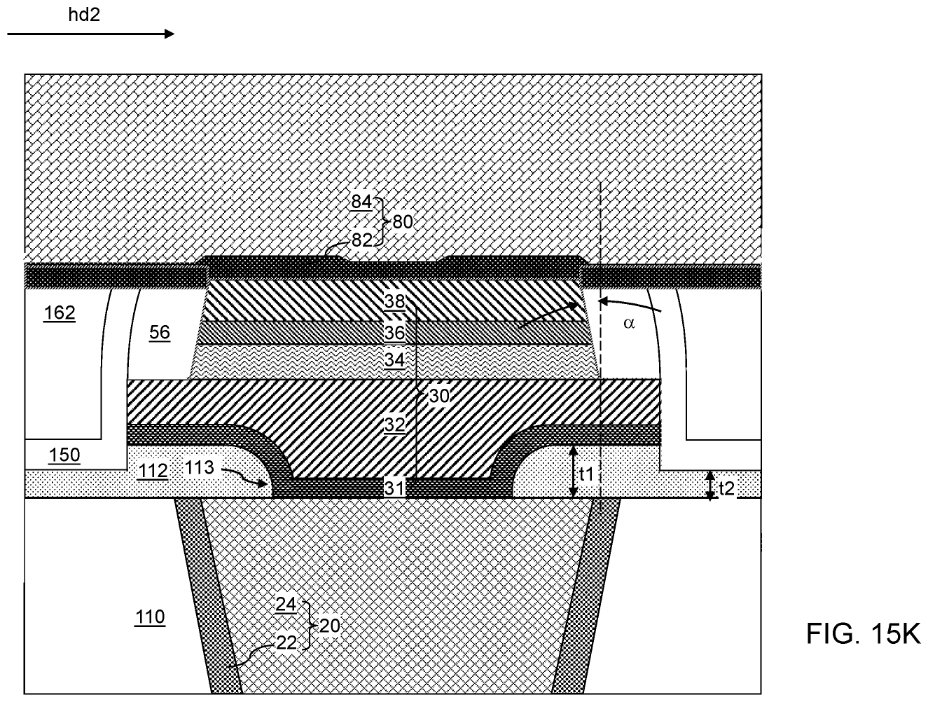

FIGS. 15A-15J are sequential vertical cross-sectional views of a region of a third embodiment structure during formation of a resistive memory cell 30 according to an embodiment of the present disclosure. FIG. 15K is a vertical cross-sectional view of an alternative configuration of the third embodiment structure according to an embodiment of the present disclosure.

Referring to FIG. 15A, a third embodiment structure according to the present disclosure may be derived from the first embodiment structure described with reference to FIGS. 2A-2C by removing the photoresist layer 75, by depositing the bottom metallic barrier material layer 31L, and by depositing the bottom metal layer 32L. The thickness of the bottom metal layer 32L may be modified such that the bottommost portion of the top surface of the bottom metal layer 32L is formed above the horizontal plane including the topmost portion of the top surface of the bottom metallic barrier material layer 31L. In one embodiment, the thickness of the bottom metal layer 32L, as measured outside the areas of the openings 113 in the etch-stop dielectric layer 112, may be in a range from 40 nm to 200 nm, such as from 80 nm to 150 nm, although lesser and greater thicknesses may also be used.

Referring to FIG. 15B, a planarization process may be performed to planarize the top surface of the bottom metal layer 32L. The entirety of the top surface of the bottom metal layer 32L may be formed within a horizontal Euclidean plane. In one embodiment, the thickness of the portion of the bottom metal layer 32L that overlies the etch-stop dielectric layer 112 may be in a range from 20 nm to 150 nm, such as from 40 nm to 100 nm, although lesser and greater thicknesses may also be used.

Referring to FIG. 15C, a continuous memory material layer 34L, an optional capping material layer 36L, a top electrode material layer 38L, and a hard mask material layer 52L may be deposited over the bottom metal layer 32L. The processing steps described with reference to FIG. 3A may be performed to deposit the continuous memory material layer 34L, the optional capping material layer 36L, the top electrode material layer 38L, and the hard mask material layer 52L.

Referring to FIG. 15D, the processing steps described with reference to FIG. 3B may be performed to pattern the continuous memory material layer 34L, the optional capping material layer 36L, the top electrode material layer 38L, and the hard mask material layer 52L. As discussed above, the first anisotropic etch process may use an etch chemistry that minimizes erosion of the hard mask plates 52. In this embodiment, the first anisotropic etch process may use a hydrogen-free etchant such as CF₄ or SF₆ to sustain a substantially vertical sidewall profile for the hard mask plates 52. A tapered surface may extend straight from the periphery of the top surface of a hard mask plate 52 to a top surface of the bottom electrode material layer (31L, 32L) at a taper angle α with respect to a vertical direction. The taper angle α may be in a range from 5 degrees to 20 degrees, such as from 5 degrees to 15 degrees. The array of patterned photoresist material portions 77 may be subsequently removed, for example, by ashing.

Referring to FIG. 15E, the processing steps described with reference to FIG. 3C may be performed to pattern the bottom electrode material layer (31L, 32L). The third embodiment structure at this processing step may be substantially the same as the first embodiment structure described with reference to FIG. 3C except that the entirety of the top surface of each bottom electrode (31, 32) is formed within a horizontal plane that contains the entirety of the bottom surface of an overlying memory material layer 34, and except that all top surfaces and the bottom surfaces of the hard mask plates 52, the top electrodes 38, the capping material plates 36, and the memory material layers 34 are formed as horizontal surfaces. In the third embodiment structure, a dielectric spacer 56 may be in contact with an entirety of the tapered surface of a stack of a memory material layer 34, a capping material plate 36, a top electrode 38, and a hard mask plate 52. The dielectric spacer 56 laterally surrounds the stack of the memory material layer 34, the capping material plate 36, the top electrode 38, and the hard mask plate 52. In one embodiment, an annular bottom surface of the dielectric spacer 56 is in contact with an annular surface segment of the etch-stop dielectric layer 112.

Referring to FIG. 15F, the processing steps described with reference to FIGS. 4A and 4B may be performed to form a dielectric capping layer 150, a memory-level dielectric layer 162, and a dielectric pad layer 166. In this embodiment, the dielectric capping layer 150 may be formed on the convex outer sidewalls of the dielectric spacers 56 and on the sidewalls of the bottom electrodes (31, 32).

Referring to FIG. 15G, the processing steps described with reference to FIGS. 5A and 5B may be performed to form first openings 81 and second openings 71 (See FIG. 5A) through the dielectric pad layer 166.

Referring to FIG. 15H, the processing steps described with reference to FIGS. 6A and 6B may be performed to form first contact via cavities 88 and second contact via cavities 78 (See FIG. 6A).

Referring to FIG. 15I, the processing steps described with reference to FIGS. 7A-7C may be performed to form top electrode contact structures 80 and peripheral metal interconnect structures 70 (See FIGS. 7A and 7C).

Referring to FIG. 15J, the processing steps described with reference to FIGS. 8A-8C may be performed to form a line-level dielectric material layer 168, which may be incorporated into the fifth line-and-via-level dielectric material layer 650. Various fifth metal line structures 658 may be formed in the line-level dielectric material layer 168 to provide electrical connection to the top electrode contact structures 80 and the peripheral metal interconnect structures 70.

Referring to FIG. 15K, an alternative configuration of the third embodiment structure may be derived from the third embodiment structure illustrated in FIG. 15F by performing the processing steps described with reference to FIGS. 9, 10A and 10B, 11A and 11B, and 12A-12D.

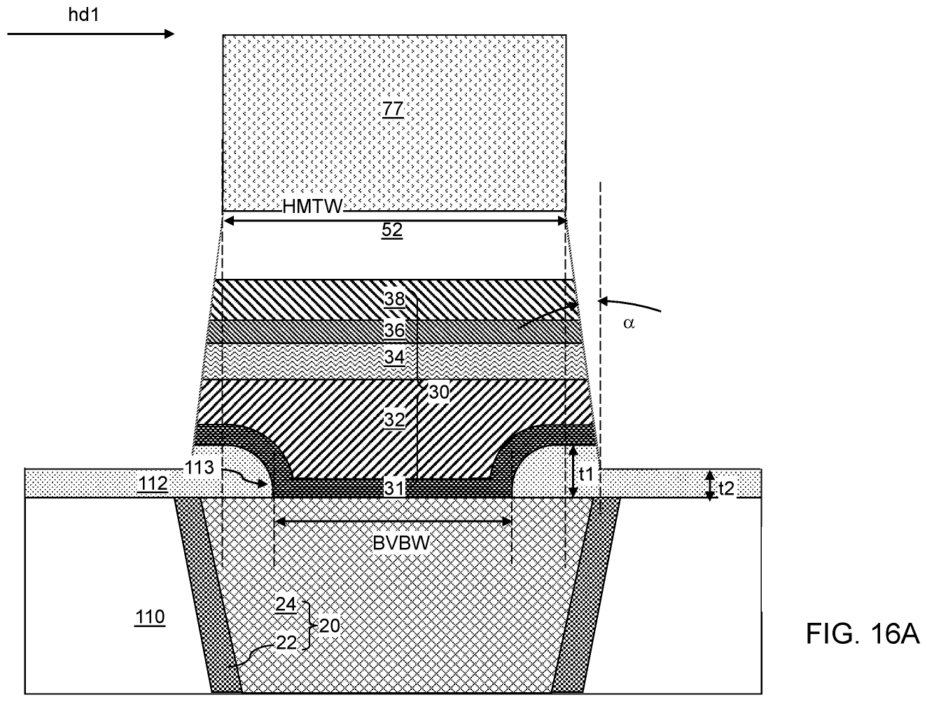

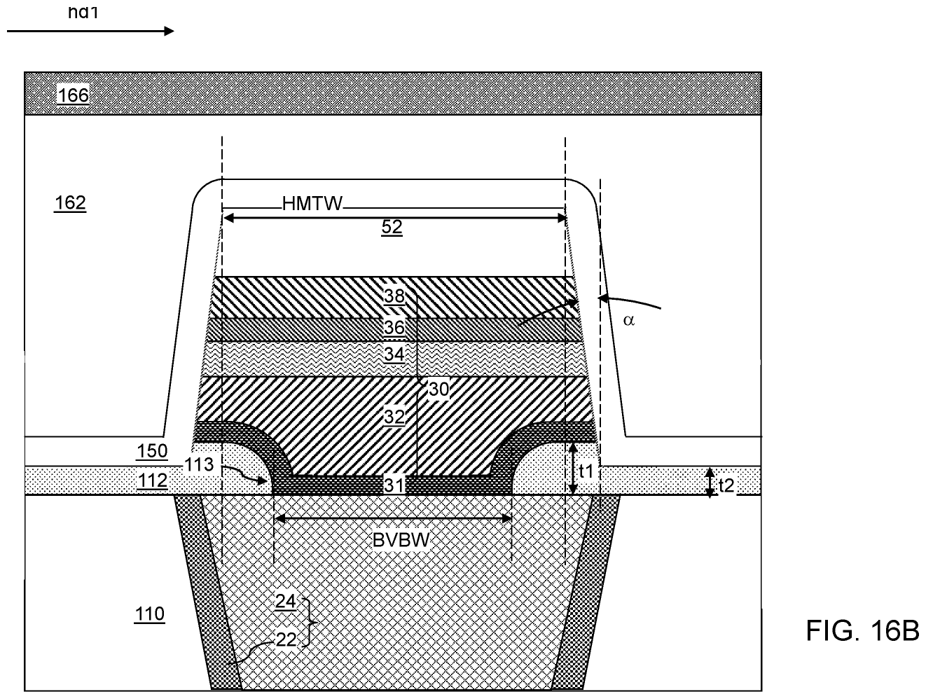

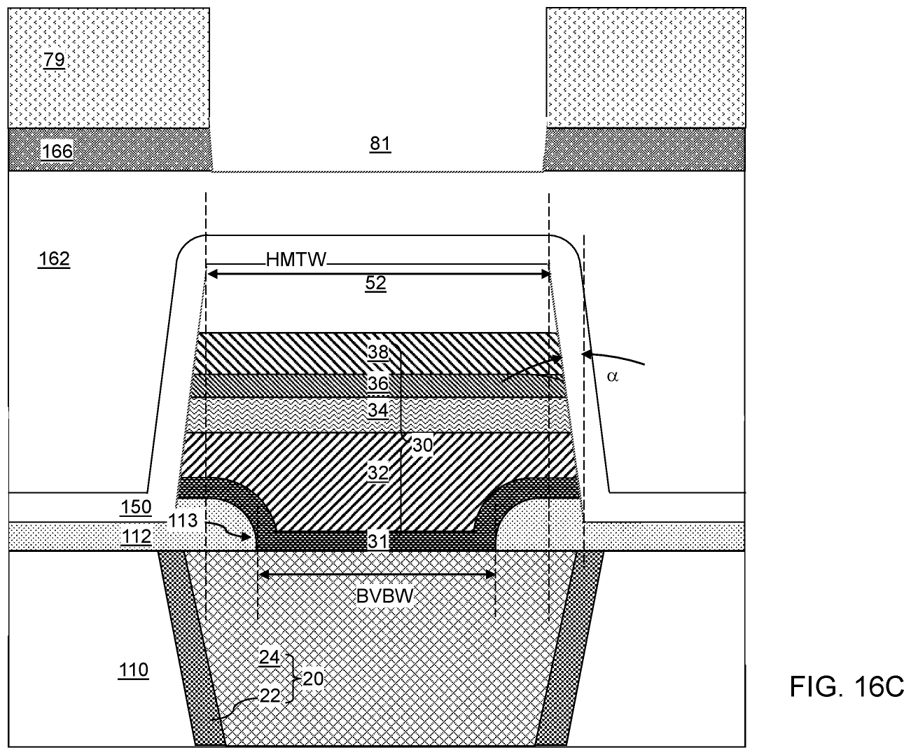

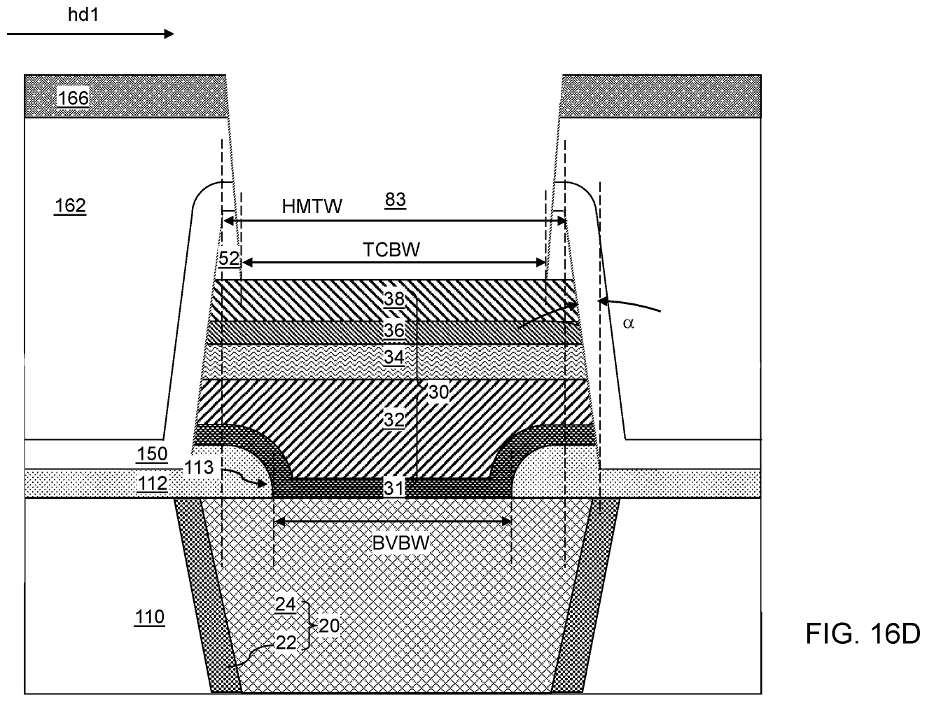

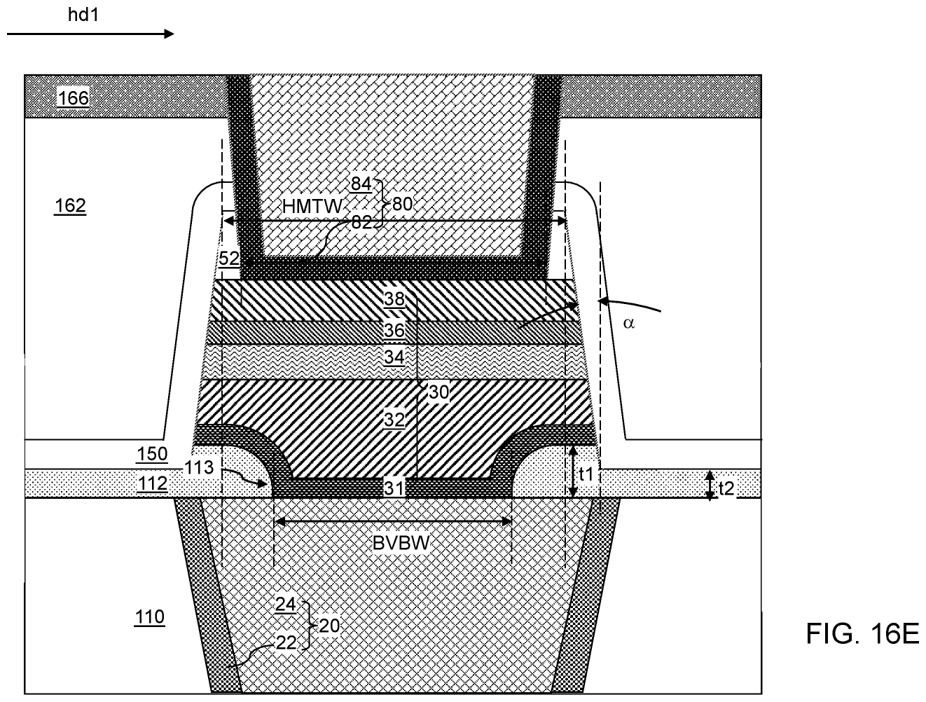

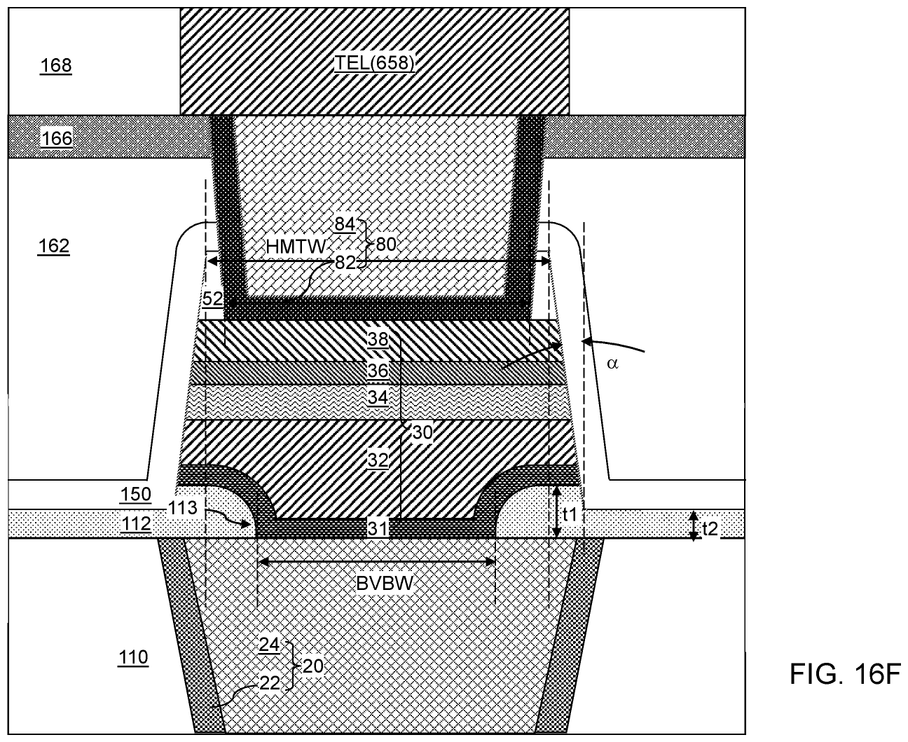

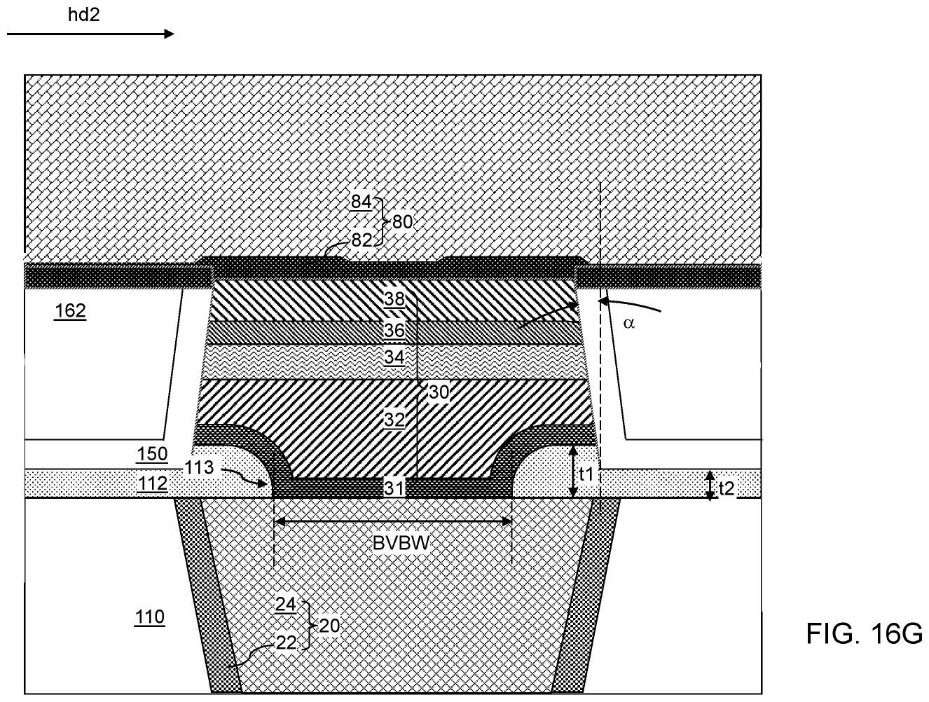

FIGS. 16A-16F are sequential vertical cross-sectional views of a region of a fourth embodiment structure during formation of a resistive memory cell 30 according to an embodiment of the present disclosure. FIG. 16G is a vertical cross-sectional view of an alternative configuration of the fourth embodiment structure according to an embodiment of the present disclosure.

Referring to FIG. 16A, a fourth embodiment structure of the present disclosure may be derived from the third embodiment structure illustrated in FIG. 15D by performing a second anisotropic etch process after performing the first anisotropic etch process. In this embodiment, the patterned photoresist material portions 77 may be used as the etch mask for the second anisotropic etch process. Unmasked portions of the bottom electrode material layer (31L, 32L) may be etched. The second anisotropic etch process may collaterally etch unmasked portions of the etch-stop dielectric layer 112. Etched portions of the etch-stop dielectric layer 112 may have a second thickness t2 which is less than the first thickness t1. The patterned photoresist material portions 77 may be subsequently removed, for example, by ashing.

Each patterned portion of the bottom electrode material layer (31L, 32L) constitutes a bottom electrode (31, 32). Each bottom electrode (31, 32) may comprise a combination of a bottom metallic barrier layer 31 and a bottom metal plate 32. The bottom metallic barrier layer 31 may be a patterned portion of the bottom metallic barrier material layer 31L, and the bottom metal plate 32 may be a patterned portion of the bottom metal layer 32L.

In one embodiment, each bottom electrode (31, 32) may comprise a top surface that includes an annular top surface segment and a central recessed horizontal surface segment that underlies a downward-protruding portion of an overlying memory material layer 34. According to an aspect of the present disclosure, the lateral extent of the central recessed horizontal surface segment along the first horizontal direction hd1 is less than a first width (such as a bottom-electrode via bottom width BVBW) of an underlying opening 113 in the etch-stop dielectric layer 112.

The thickness of a horizontally-extending portion of each hard mask plate 52 may be in a range from 25 nm to 180 nm, and/or from 40 nm to 100 nm, although lesser and greater thicknesses may also be used. The periphery of the top surface of each hard mask plate 52 may have a second width along the first horizontal direction hd1, which is herein referred to as a hard mask top width HMTW. The second width is greater than the first width (such as a bottom-electrode via bottom width BVBW).

Generally, the top electrode material layer 38L, the continuous memory material layer 34L, and the bottom electrode material layer (31L, 32L) may be patterned into a two-dimensional array of resistive memory cells 30. Each resistive memory cell 30 comprises a top electrode 38, an optional capping material plate 36, a memory material layer 34, and a bottom electrode (31, 32). In one embodiment, each bottom electrode (31, 32) comprises a plate portion overlying the etch-stop dielectric layer 112 and a via portion located within the opening 113 in the etch-stop dielectric layer 112. In other words, the via portion vertically extends downward into a respective opening 113 in the etch-stop dielectric layer 112. In one embodiment, the memory material layer 34 overlies the bottom electrode (31, 32) and is configured to provide at least two states having different electrical resistance. In one embodiment, within each resistive memory cell 30, the memory material layer 34 is located entirely within an area of a top surface of an underlying bottom connection via structure 20 (which is a metallic via structure) in a plan view upon patterning of the memory material layer 34. The top electrode 38 overlies the memory material layer 34.

As discussed above, the first anisotropic etch process may use an etch chemistry that minimizes erosion of the hard mask plates 52. In this embodiment, the first anisotropic etch process may use a hydrogen-free etchant such as CF₄ or SF₆ to sustain a substantially vertical sidewall profile for the hard mask plates 52. A tapered surface may extend straight from the periphery of the top surface of a hard mask plate 52 at least to a periphery of a bottom surface of a bottom electrode (31,32) at a taper angle α with respect to a vertical direction. The taper angle α may be in a range from 5 degrees to 20 degrees, such as from 5 degrees to 15 degrees. The array of patterned photoresist material portions 77 may be subsequently removed, for example, by ashing. In one embodiment, a tapered surface may extend straight from the periphery of the top surface of a hard mask plate 52 to a periphery of a portion of the etch-stop dielectric layer 112 having the second thickness t2 at the taper angle α with respect to a vertical direction.

In one embodiment, the etch-stop dielectric layer 112 comprises an annular portion that laterally surrounds an opening 113 in the etch-stop dielectric layer 112 and having a first thickness t1, and a planar layer portion having a second thickness t2 that is less than the first thickness t1 and laterally spaced from the opening 113 by the annular portion. Thus, the annular portion has the first thickness t1 and includes an opening 113 therethrough, and the planar layer portion has a second thickness t2 that is less than the first thickness t1 and is laterally spaced from the opening 113 by the annular portion.

The fourth embodiment structure at this processing step may be substantially the same as the second embodiment structure described with reference to FIG. 14A except that the entirety of the top surface of each bottom electrode (31, 32) is formed within a horizontal plane that contains the entirety of the bottom surface of an overlying memory material layer 34, and except that all top surfaces and the bottom surfaces of the hard mask plates 52, the top electrodes 38, the capping material plates 36, and the memory material layers 34 are formed as horizontal surfaces.

Referring to FIG. 16B, the processing steps described with reference to FIGS. 4A and 4B may be performed to form a dielectric capping layer 150, a memory-level dielectric layer 162, and a dielectric pad layer 166. In this embodiment, the dielectric capping layer 150 may be formed directly on straight sidewalls of the resistive memory cells 30.

Referring to FIG. 16C, the processing steps described with reference to FIGS. 5A and 5B may be performed to form first openings 81 and second openings 71 (See FIG. 5A) through the dielectric pad layer 166.

Referring to FIG. 16D, the processing steps described with reference to FIGS. 6A and 6B may be performed to form first contact via cavities 88 and second contact via cavities 78 (See FIG. 6A).

Referring to FIG. 16E, the processing steps described with reference to FIGS. 7A-7C may be performed to form top electrode contact structures 80 and peripheral metal interconnect structures 70 (See FIGS. 7A and 7C).

Referring to FIG. 16F, the processing steps described with reference to FIGS. 8A-8C may be performed to form a line-level dielectric material layer 168, which may be incorporated into the fifth line-and-via-level dielectric material layer 650. Various fifth metal line structures 658 may be formed in the line-level dielectric material layer 168 to provide electrical connection to the top electrode contact structures 80 and the peripheral metal interconnect structures 70.

Referring to FIG. 16G, an alternative configuration of the fourth embodiment structure may be derived from the fourth embodiment structure illustrated in FIG. 14B by performing the processing steps described with reference to FIGS. 9, 10A and 10B, 11A and 11B, and 12A-12D.

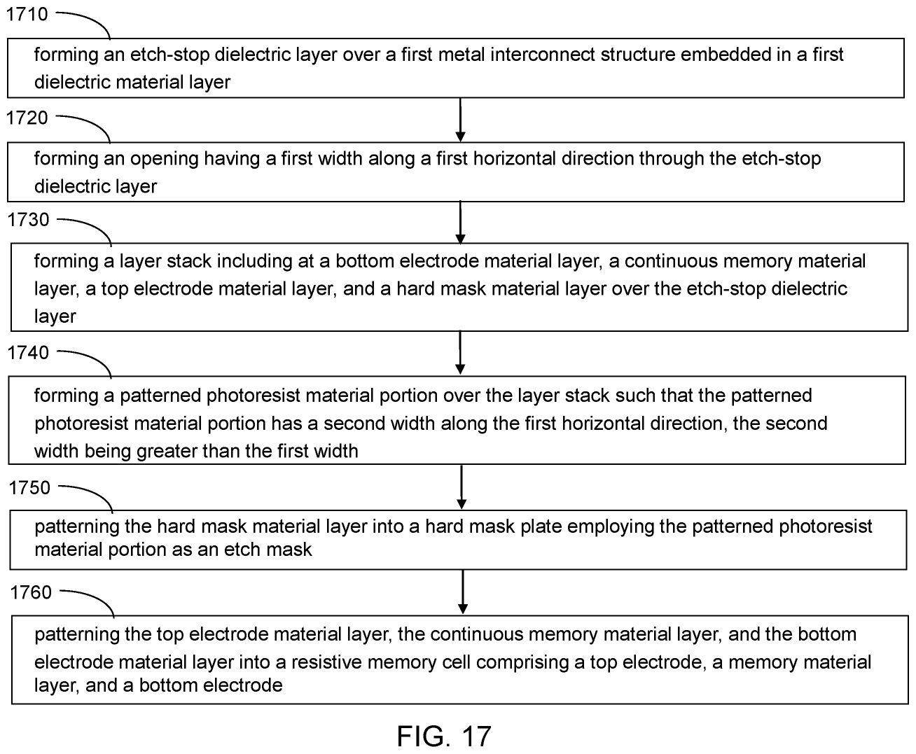

Referring to FIG. 17, a flowchart illustrates a sequence of processing steps for manufacturing a resistive memory device of the present disclosure.

Referring to step 1710 and FIGS. 1, 2A, 2B, and 2C, an etch-stop dielectric layer 112 may be formed over a first metal interconnect structure (such as a bottom connection via structure 20) in a first dielectric material layer (such as a lower connection-via-level dielectric layer 110).

Referring to step 1720 and FIGS. 2A, 2B, and 2C, an opening 113 having a first width (such as a bottom-electrode via bottom width BVBW) along a first horizontal direction hd1 may be formed through the etch-stop dielectric layer 112.

Referring to step 1730 and FIGS. 3A and 15A-15C, a layer stack including at a bottom electrode material layer (31L, 32L), a continuous memory material layer 34L, a top electrode material layer 38L, and a hard mask material layer 52L may be formed over the etch-stop dielectric layer 112.

Referring to step 1740 and FIGS. 3B, 14A, 15D, and 16A, a patterned photoresist material portion 77 may be formed over the layer stack such that the patterned photoresist material portion 77 has a second width (which may, or may not, be the same as a hard mask top width HMTW) along the first horizontal direction hd1. The second width (such as a hard mask top width HMTW) is greater than the first width (such as a bottom-electrode via bottom width BVBW).

Referring to step 1750 and FIGS. 3B, 14A, 15D, and 16A, the hard mask material layer 52L may be patterned into a hard mask plate 52 using the patterned photoresist material portion 77 as an etch mask.

Referring to step 1760 and FIGS. 3B-13, 14A-14F, 15D-15J, and 16A-16F, the top electrode material layer 38L, the continuous memory material layer 34L, and the bottom electrode material layer (31L, 32L) may be patterned into a resistive memory cell 30 comprising a top electrode 38, a memory material layer 34, and a bottom electrode (31, 32).

Referring to all drawings and according to various embodiments of the present disclosure, a device structure is provided, which comprises, a first metal interconnect structure (such as a bottom connection via structure 20) formed in a first dielectric material layer (such as a lower connection-via-level dielectric layer 110); an etch-stop dielectric layer 112 overlying the first dielectric material layer (such as a lower connection-via-level dielectric layer 110) and having an opening 113 having a first width (such as a bottom-electrode via bottom width BVBW) along a first horizontal direction hd1; a resistive memory cell 30 comprising a stack of a bottom electrode (31, 32), a memory material layer 34, and a top electrode 38, wherein the bottom electrode (31, 32) comprises a plate portion overlying the etch-stop dielectric layer 112 and a via portion located within the opening 113 in the etch-stop dielectric layer 112, the memory material layer 34 overlies the bottom electrode (31, 32) and is configured to provide at least two states having different electrical resistance, and the top electrode 38 overlies the memory material layer 34; and a hard mask plate 52 overlying the top electrode 38, wherein a periphery of a top surface of the hard mask plate 52 has a second width (such as a hard mask top width HMTW) along the first horizontal direction hd1 that is greater than the first width (such as a bottom-electrode via bottom width BVBW).

In one embodiment, the device structure comprises: a memory-level dielectric layer 162 laterally surrounding the bottom electrode (31, 32), the memory material layer 34, and the top electrode 38; and a top electrode contact structure 80 vertically extending through an upper portion of the memory-level dielectric layer 162 and contacting a top surface of the top electrode 38. In one embodiment, a bottom surface of the top electrode contact structure 80 has a third width (such as a top-contact-structure bottom width TCBW) along the first horizontal direction hd1 that is less than the second width (such as a hard mask top width HMTW) and greater than the first width (such as a bottom-electrode via bottom width BVBW). In one embodiment, the device structure comprises a hard mask divot-fill material portion 52′ located within a divot in the top surface of the top electrode 38, contacting a divot-shaped segment of the top surface of the top electrode 38 and underlying a bottom surface of the top electrode contact structure 80.

In one embodiment, the opening 113 in the etch-stop dielectric layer 112 has a shape of a circle, an oval, or a rounded rectangle; and the first width (such as a bottom-electrode via bottom width BVBW) is a diameter, a minor axis, or a distance between a pair of parallel segments. In one embodiment, the etch-stop dielectric layer 112 comprises an annular portion that laterally surrounds the opening 113 and having a first thickness t1, and a planar layer portion having a second thickness t2 that is less than the first thickness t1 and laterally spaced from the opening 113 by the annular portion. In one embodiment, a tapered surface extends straight from the periphery of the top surface of the hard mask plate 52 at least to a top surface of the bottom electrode (31, 32) at a taper angle α with respect to a vertical direction. The taper angle α may be in a range from 5 degrees to 20 degrees.

In one embodiment, the device structure comprises a dielectric spacer 56 in contact with an entirety of the tapered surface and laterally surrounding the top electrode 38 and the memory material layer 34. In one embodiment, an annular bottom surface of the dielectric spacer 56 is in contact with an annular surface segment of the etch-stop dielectric layer 112. In one embodiment, an annular bottom surface of the dielectric spacer 56 is in contact with an annular surface segment of a top surface of the bottom electrode (31, 32).

According to another aspect of the present disclosure, a device structure is provided, which comprises, an etch-stop dielectric layer 112 comprises an annular portion having a first thickness t1 and including an opening 113 therethrough, and a planar layer portion having a second thickness t2 that is less than the first thickness t1 and laterally spaced from the opening 113 by the annular portion, wherein the opening 113 has a first width (such as a bottom-electrode via bottom width BVBW) along a first horizontal direction hd1; a resistive memory cell 30 comprising a stack of a bottom electrode (31, 32), a memory material layer 34, and a top electrode 38, the bottom electrode (31, 32) comprises a via portion that vertically extends downward into the opening 113 in the etch-stop dielectric layer 112; and a hard mask plate 52 overlying the top electrode 38, wherein a periphery of a top surface of the hard mask plate 52 has a second width (such as a hard mask top width HMTW) along the first horizontal direction hd1 that is greater than the first width (such as a bottom-electrode via bottom width BVBW), wherein a tapered surface extends straight from the periphery of the top surface of the hard mask plate 52 at least to a top surface of the bottom electrode (31, 32) at a taper angle α with respect to a vertical direction. The taper angle α may be in a range from 5 degrees to 20 degrees.

In one embodiment, the device structure comprises a dielectric capping layer 150 laterally surrounding the resistive memory cell 30, contacting a cylindrical sidewall of the etch-stop dielectric layer 112 connecting a periphery of a top surface of the annular portion of the etch-stop dielectric layer 112 and a periphery of a top surface of the planar layer portion of the etch-stop dielectric layer 112, contacting a sidewall of the bottom electrode (31, 32), and contacting the top surface of the hard mask plate 52.

In one embodiment, the device structure comprises: a memory-level dielectric layer 162 overlying a horizontally-extending portion of the dielectric capping layer 150 and laterally surrounding a portion of the dielectric capping layer 150 that protrudes above the horizontally-extending portion of the dielectric capping layer 150; and a top electrode contact structure 80 vertically extending through an upper portion of the memory-level dielectric layer 162, the dielectric capping layer 150, and contacting a top surface of the top electrode 38. In one embodiment, a bottom surface of the top electrode contact structure 80 has a third width (such as a top-contact-structure bottom width TCBW) along the first horizontal direction hd1 that is less than the second width (such as a hard mask top width HMTW) and greater than the first width (such as a bottom-electrode via bottom width BVBW).

In one embodiment, a top surface of the bottom electrode (31, 32) comprises an annular top surface segment and a central recessed horizontal surface segment that underlies a downward-protruding portion of the memory material layer 34, wherein a lateral extent of the central recessed horizontal surface segment along the first horizontal direction hd1 is less than the first width (such as a bottom-electrode via bottom width BVBW).

The various embodiments of the present disclosure may be used to provide top electrode contact structures 80 that increases the contact area with a respective top electrode 38, and to provide hard mask plates 52 with reduced sidewall erosion. Specifically, the sidewalls of the hard mask plates 52 are formed in areas that are sufficiently laterally offset from any topography that may be present around a center region of a resistive memory cell 30. Thus, the sidewalls of the hard mask plates 52 may be formed without contour and with a reduced taper angle. The use of hydrogen-free etchant gas may further reduce the taper angle of the sidewalls of the hard mask plates 52. The absence of a large taper angle in the hard mask plates 52 provides formation of the top electrode contact structures 80 with a sufficiently large contact area with the top electrodes 38, thereby increasing the process yield and the reliability of the electrical contact between the top electrodes 38 and the top electrode contact structures 80. The top electrode contact structures 80 may be formed as metal via structures or as metal line structures.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph of in different paragraphs, a Markush group including a listing of the two or more elements may be also impliedly disclosed in some embodiments. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device structure comprising,
a first metal interconnect structure formed in a first dielectric material layer;
an etch-stop dielectric layer overlying the first dielectric material layer and having an opening having a first width along a first horizontal direction;
a resistive memory cell comprising a stack of a bottom electrode, a memory material layer, and a top electrode, wherein the bottom electrode comprises a plate portion overlying the etch-stop dielectric layer and a via portion located within the opening in the etch-stop dielectric layer, the memory material layer overlies the bottom electrode, and the top electrode overlies the memory material layer; and
a hard mask plate overlying the top electrode, wherein a periphery of a top surface of the hard mask plate has a second width along the first horizontal direction that is greater than the first width.

2. The device structure of claim 1, further comprising:
a memory-level dielectric layer laterally surrounding the bottom electrode, the memory material layer, and the top electrode; and
a top electrode contact structure vertically extending through an upper portion of the memory-level dielectric layer and contacting a top surface of the top electrode.

3. The device structure of claim 2, wherein a bottom surface of the top electrode contact structure has a third width along the first horizontal direction that is less than the second width and greater than the first width.

4. The device structure of claim 2, further comprising a hard mask divot-fill material portion located within a divot in the top surface of the top electrode, contacting a divot-shaped segment of the top surface of the top electrode and underlying a bottom surface of the top electrode contact structure.

5. The device structure of claim 1, wherein:
the opening in the etch-stop dielectric layer has a shape of a circle, an oval, or a rounded rectangle; and
the first width is a diameter, a minor axis, or a distance between a pair of parallel segments.

6. The device structure of claim 1, wherein;
memory material layer is configured to provide at least two states having different electrical resistance; and
the etch-stop dielectric layer comprises an annular portion that laterally surrounds the opening and having a first thickness, and a planar layer portion having a second thickness that is less than the first thickness and laterally spaced from the opening by the annular portion.

7. The device structure of claim 6, wherein a tapered surface extends straight from the periphery of the top surface of the hard mask plate at least to a top surface of the bottom electrode at a taper angle with respect to a vertical direction, the taper angle being in a range from 5 degrees to 20 degrees.

8. The device structure of claim 7, further comprising a dielectric spacer in contact with an entirety of the tapered surface and laterally surrounding the top electrode and the memory material layer.

9. The device structure of claim 8, wherein an annular bottom surface of the dielectric spacer is in contact with an annular surface segment of the etch-stop dielectric layer.

10. The device structure of claim 8, wherein an annular bottom surface of the dielectric spacer is in contact with an annular surface segment of a top surface of the bottom electrode.

11. A device structure comprising,
an etch-stop dielectric layer comprises an annular portion having a first thickness and including an opening therethrough, and a planar layer portion having a second thickness that is less than the first thickness and laterally spaced from the opening by the annular portion, wherein the opening has a first width along a first horizontal direction;
a resistive memory cell comprising a stack of a bottom electrode, a memory material layer, and a top electrode, the bottom electrode comprises a via portion that vertically extends downward into the opening in the etch-stop dielectric layer; and
a hard mask plate overlying the top electrode, wherein a periphery of a top surface of the hard mask plate has a second width along the first horizontal direction that is greater than the first width,
wherein a tapered surface extends straight from the periphery of the top surface of the hard mask plate at least to a top surface of the bottom electrode at a taper angle with respect to a vertical direction.

12. The device structure of claim 11, further comprising a dielectric capping layer laterally surrounding the resistive memory cell, contacting a cylindrical sidewall of the etch-stop dielectric layer connecting a periphery of a top surface of the annular portion of the etch-stop dielectric layer and a periphery of a top surface of the planar layer portion of the etch-stop dielectric layer, contacting a sidewall of the bottom electrode, and contacting the top surface of the hard mask plate.

13. The device structure of claim 12, further comprising:
a memory-level dielectric layer overlying a horizontally-extending portion of the dielectric capping layer and laterally surrounding a portion of the dielectric capping layer that protrudes above the horizontally-extending portion of the dielectric capping layer; and
a top electrode contact structure vertically extending through an upper portion of the memory-level dielectric layer, the dielectric capping layer, and contacting a top surface of the top electrode.

14. The device structure of claim 13, wherein a bottom surface of the top electrode contact structure has a third width along the first horizontal direction that is less than the second width and greater than the first width.

15. The device structure of claim 11, wherein:
the taper angle is in a range from 5 degrees to 20 degrees; and
a top surface of the bottom electrode comprises an annular top surface segment and a central recessed horizontal surface segment that underlies a downward-protruding portion of the memory material layer, wherein a lateral extent of the central recessed horizontal surface segment along the first horizontal direction is less than the first width.

16. A method of forming a device structure, comprising:
forming an etch-stop dielectric layer over a first metal interconnect structure formed in a first dielectric material layer;
forming an opening having a first width along a first horizontal direction through the etch-stop dielectric layer;
forming a layer stack including at a bottom electrode material layer, a continuous memory material layer, a top electrode material layer, and a hard mask material layer over the etch-stop dielectric layer;
forming a patterned photoresist material portion over the layer stack such that the patterned photoresist material portion has a second width along the first horizontal direction, the second width being greater than the first width;
patterning the hard mask material layer into a hard mask plate using the patterned photoresist material portion as an etch mask; and
patterning the top electrode material layer, the continuous memory material layer, and the bottom electrode material layer into a resistive memory cell comprising a top electrode, a memory material layer, and a bottom electrode.

17. The method of claim 16, wherein the patterned photoresist material portion covers an entirety of an area of the opening in a plan view.

18. The method of claim 16, further comprising:
forming a memory-level dielectric layer around, and over, the resistive memory cell;
forming a contact cavity through the memory-level dielectric layer such that a surface segment of the top electrode is exposed to the contact via cavity; and
forming a top electrode contact structure in the contact cavity on the surface segment of the top electrode.

19. The method of claim 18, wherein:
a bottom surface of the top electrode contact structure has a third width along the first horizontal direction; and
the third width is less than the second width and is greater than the first width.

20. The method of claim 16, wherein:
the first metal interconnect structure comprises a metallic via structure; and
the memory material layer is located entirely within an area of a top surface of the metallic via structure in a plan view upon patterning of the memory material layer.
